(19) United States
(12) Patent Application Publication
(10) Pub. No.: US 2010/0081285 A1
(43) Pub. Date: Apr. 1, 2010

(54) Apparatus and Method for Improving Photoresist Properties

(75) Inventors: Lee Chen, Cedar Creek, TX (US); Merritt Funk, Austin, TX (US); Radha Sundararajan, Dripping Springs, TX (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/242,065

(22) Filed: Sep. 30, 2008

(51) Int. Cl. H01L 21/3065

(52) U.S. Cl. 438/710; 156/345.26; 257/E21.218

(57) ABSTRACT

The invention can provide apparatus and methods of processing a substrate in real-time using subsystems and processing sequences created to improve the etch resistance of photoresist materials. In addition, the improved photoresist layer can be used to more accurately control gate and/or spacer critical dimensions (CDs), to control gate and/or spacer CD uniformity, and to eliminate line edge roughness (LER) and line width roughness (LWR).

### BACKGROUND OF THE INVENTION

1. Field of the Invention

The present invention relates to substrate processing, and more particularly to improving the substrate processing using photoresist curing procedures, and subsystems.

2. Description of the Related Art

Etch process behavior is inherently non-linear, and interactive from step-to-step (layers) or as process stacks are compiled (etch/cvd/implant). With the knowledge of the process interactions based on physical modeling of process chambers and base processes and imperial data and measurements from process refinement and tuning the control of Critical Dimension (CD), Sidewall Angle (SWA), depths, film thicknesses, over etching, undercuts, surface cleaning and damage control can be recursively calculated and optimized using multi-input multi-output non-linear models. Current low cost products use a bulk silicon technology. As the transistor continues to shrink, the impact of the channel depth is becoming critical (ultra-shallow source/drain extensions). As the SOI film shrinks, smaller variations in the gate and/or spacer thickness and thickness of the SOI film can affect the transistor's performance. When etch procedures are not controlled, the removal of the material near the gate affects the electrical performance.

Current high performance microprocessors use PD SOI (partially depleted Silicon-on-Insulator) films that give a threshold voltage of 0.2 volts. PD SOI films are around 50 nm (nanometers) while the gate and/or spacer reduction amount can be a large fraction (10%) of the total gate and/or spacer thickness. Future generations of SOI films are called FD SOI (fully depleted SOI) that gives a threshold voltage of 0.08 volts for a thickness of ˜25 nm. Currently, theses films are not in production due to limitations in thickness control uniformity and defects. Channel mobility degrades with decreasing SOI thickness. With thinner SOI film, the control of the gate and/or spacer sidewall thickness becomes more critical.

### SUMMARY OF THE INVENTION

The invention can provide apparatus and methods of processing a substrate in real-time using subsystems and processing sequences created to cure and/or harden radiation-sensitive materials. In addition, the hardened resist layer can be used to more accurately control gate and/or spacer critical dimensions (CDs), to control gate and/or spacer CD uniformity, and to eliminate line edge roughness (LER) and line width roughness (LWR).

Other aspects of the invention will be made apparent from the description that follows and from the drawings appended hereto.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 shows an exemplary block diagram of a processing system in accordance with embodiments of the invention;

FIG. 2 shows an exemplary block diagram of a Photoresist-Hardening (P-H) subsystem in accordance with embodiments of the invention;

FIG. 3 shows an exemplary block diagram of another Photoresist-Hardening (P-H) subsystem in accordance with embodiments of the invention;

FIG. 4 illustrates exemplary block diagrams of additional Photoresist-Hardening (P-H) subsystems in accordance with embodiments of the invention;

FIG. 5 illustrates an exemplary view of a first Photoresist-Hardening (P-H) procedure using a metal gate structure in accordance with embodiments of the invention;

FIG. 6 illustrates a simplified flow diagram of a procedure for processing substrates using a Photoresist-Hardening (P-H) procedure in accordance with embodiments of the invention; and

FIG. 7 illustrates a simplified flow diagram of a procedure for processing substrates using a Photoresist-Hardening (P-H) procedure in accordance with embodiments of the invention.

### DETAILED DESCRIPTION

The invention provides apparatus and methods of processing a substrate in real-time using subsystems and processing sequences created to cure and/or harden photoresist materials. In addition, the hardened photoresist layer can be used to more accurately control gate and/or spacer critical dimensions (CDs), to control gate and/or spacer CD uniformity, and to eliminate line edge roughness (LER) and line width roughness (LWR).

In some embodiments, apparatus and methods are provided for creating and/or using a metrology library that includes profile data and diffraction signal data for cured and/or hardened photoresist features and periodic structures.

One or more evaluation features can be provided at various locations on a substrate and can be used to evaluate and/or verify photoresist-hardening (P-H) procedures and associated models. Substrates can have real-time and historical data associated with them, and the substrate data can include P-H related data. In addition, the substrate can have other data associated with them, and the other data can include gate structure data, the number of required sites, the number of visited sites, confidence data and/or risk data for one or more of the sites, site ranking data, transferring sequence data, or process-related data, or evaluation/verification-related data, or any combination thereof. The data associated with substrates can include transfer sequence data that can be used to establish when and where to transfer the substrates, and transfer sequences can be changed using operational state data.

During photoresist hardening, a dry plasma process can be utilized, and the plasma is formed from a process gas by coupling electromagnetic (EM) energy, such as radio frequency (RF) power, to the process gas in order to heat electrons and cause subsequent ionization and dissociation of the atomic and/or molecular composition of the process gas. In addition, negative, high voltage direct current (DC) electrical power can be coupled to the plasma processing system in order to create an energetic (ballistic) electron beam that strikes the substrate surface during a fraction of the RF cycle, i.e., the positive half-cycle of the coupled RF power. It has been observed that the ballistic electron beam can enhance the properties of the dry plasma etching process. Details regarding the use of DC electrodes are disclosed in pending U.S. patent application Ser. No. 11/156,559, entitled “Plasma Processing Apparatus and Method” and published as US patent application no. 2006/0037701A1; the entire contents of which are herein incorporated by reference in their entirety. Additional details regarding the use of DC electrodes are disclosed in pending U.S. patent application Ser. No. 11/156,561, entitled “Plasma Processing Apparatus and Method” and published as US patent application no. 2006/0037703A1; and pending U.S. patent application Ser. No. 11/157,061, entitled “Plasma Processing Apparatus and Method” and published as US patent application no. 2006/0066247A1, and the entire contents of these two patent applications are herein incorporated by reference in their entirety.

As feature sizes decrease below the 65 nm technology node, accurate processing and/or measurement data becomes more important and more difficult to obtain. P-H procedures can be used to more accurately process and/or measure these ultra-small devices and features. The data from a P-H procedure can be compared with the warning and/or control limits. When a run-rule is violated, an alarm can be generated indicating a processing problem, and correction procedures can be performed in real time.

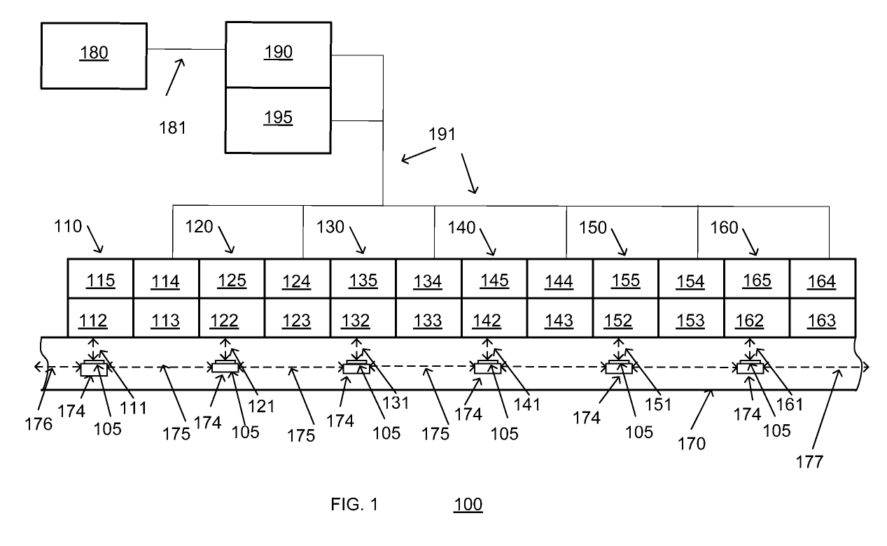

FIG. 1 shows an exemplary block diagram of a processing system in accordance with embodiments of the invention. In the illustrated embodiment, processing system 100 comprises a lithography subsystem 110, a scanner subsystem 120, an etch subsystem 130, a deposition subsystem 140, a photoresist-hardening (P-H) subsystem 150, an evaluation subsystem 160, a transfer subsystem 170, a manufacturing execution system (MES) 180, a system controller 190, and a memory/database 195. Single subsystems (110, 120, 130, 140, 150, 160, and 170) are shown in the illustrated embodiment, but this is not required for the invention. In some embodiments, multiple subsystems (110, 120, 130, 140, 150, 160, and 170) can be used in a processing system 100. In addition, one or more of the subsystems (110, 120, 130, 140, 150, 160, and 170) can comprise one or more processing elements that can be used in multi-layer multi-input multi-output (MLMIMO) models and associated processing sequences.

The system controller 190 can be coupled to the lithography subsystem 110, the scanner subsystem 120, the etch subsystem 130, the deposition subsystem 140, the P-H subsystem 150, the evaluation subsystem 160, and the transfer subsystem 170 using a data transfer subsystem 191. The system controller 190 can be coupled to the MES 180 using the data transfer subsystem 181. Alternatively, other configurations may be used. For example, the etch subsystem 130, the deposition subsystem 140, the P-H subsystem 150, the evaluation subsystem 160, and a portion of the transfer subsystem 170 can be subsystems available from Tokyo Electron Limited.

The lithography subsystem 110 can comprise one or more transfer/storage elements 112, one or more processing elements 113, one or more controllers 114, and one or more evaluation elements 115. One or more of the transfer/storage elements 112 can be coupled to one or more of the processing elements 113 and/or to one or more of the evaluation elements 115 and can be coupled 111 to the transfer subsystem 170. The transfer subsystem 170 can be coupled 111 to the lithography subsystem 110, and one or more substrates 105 can be transferred via coupling 111 between the transfer subsystem 170 and the lithography subsystem 110 in real time. For example, the transfer subsystem 170 can be coupled to one or more of the transfer/storage elements 112, to one or more of the processing elements 113, and/or to one or more of the evaluation elements 115. One or more of the controllers 114 can be coupled to one or more of the transfer/storage elements 112, to the one or more of the processing elements 113, and/or to one or more of the evaluation elements 115.

In some embodiments, the lithography subsystem 110 can perform coating procedures, thermal procedures, measurement procedures, inspection procedures, alignment procedures, and/or storage procedures on one or more substrates using procedures and/or procedures. For example, one or more lithography-related processes can be used to deposit one or more masking layers that can include photoresist material, and/or anti-reflective coating (ARC) material, and can be used to thermally process (bake) one or more of the masking layers. In addition, lithography subsystem 110 can be used to develop, measure, and/or inspect one or more of the patterned masking layers on one or more of the substrates.

The scanner subsystem 120 can comprise one or more transfer/storage elements 122, one or more processing elements 123, one or more controllers 124, and one or more evaluation elements 125. One or more of the transfer/storage elements 122 can be coupled to one or more of the processing elements 123 and/or to one or more of the evaluation elements 125 and can be coupled 121 to the transfer subsystem 170. The transfer subsystem 170 can be coupled 121 to the scanner subsystem 120, and one or more substrates 105 can be transferred via coupling 121 between the transfer subsystem 170 and the scanner subsystem 120 in real time. For example, the transfer subsystem 170 can be coupled to one or more of the transfer/storage elements 122, to one or more of the processing elements 123, and/or to one or more of the evaluation elements 125. One or more of the controllers 124 can be coupled to one or more of the transfer/storage elements 122, to the one or more of the processing elements 123, and/or to one or more of the evaluation elements 125.

In some embodiments, the scanner subsystem 120 can be used to perform wet and/or dry exposure procedures, and in other cases, the scanner subsystem 120 can be used to perform extreme ultraviolet (EUV) exposure procedures.

The etch subsystem 130 can comprise one or more transfer/storage elements 132, one or more processing elements 133, one or more controllers 134, and one or more evaluation elements 135. One or more of the transfer/storage elements 132 can be coupled to one or more of the processing elements 133 and/or to one or more of the evaluation elements 135 and can be coupled 131 to the transfer subsystem 170. The transfer subsystem 170 can be coupled 131 to the etch subsystem 130, and one or more substrates 105 can be transferred via coupling 131 between the transfer subsystem 170 and the etch subsystem 130 in real time. For example, the transfer subsystem 170 can be coupled to one or more of the transfer/storage elements 132, to one or more of the processing elements 133, and/or to one or more of the evaluation elements 135. One or more of the controllers 134 can be coupled to one or more of the transfer/storage elements 132, to the one or more of the processing elements 133, and/or to one or more of the evaluation elements 135. For example, one or more of the processing elements 133 can be used to perform plasma or non-plasma etching, ashing, and cleaning procedures, or plasma or non-plasma etching procedures. Evaluation procedures and/or inspection procedures can be used to measure and/or inspect one or more surfaces and/or layers of the substrates.

The deposition subsystem 140 can comprise one or more transfer/storage elements 142, one or more processing elements 143, one or more controllers 144, and one or more evaluation elements 145. One or more of the transfer/storage elements 142 can be coupled to one or more of the processing elements 143 and/or to one or more of the evaluation elements 145 and can be coupled 141 to the transfer subsystem 170. The transfer subsystem 170 can be coupled 141 to the deposition subsystem 140, and one or more substrates 105 can be transferred via coupling 141 between the transfer subsystem 170 and the deposition subsystem 140 in real time. For example, the transfer subsystem 170 can be coupled to one or more of the transfer/storage elements 142, to one or more of the processing elements 143, and/or to one or more of the evaluation elements 145. One or more of the controllers 144 can be coupled to one or more of the transfer/storage elements 142, to the one or more of the processing elements 143, and/or to one or more of the evaluation elements 145. For example, one or more of the processing elements 143 can be used to perform physical vapor deposition (PVD) procedures, chemical vapor deposition (CVD) procedures, ionized physical vapor deposition (iPVD) procedures, atomic layer deposition (ALD) procedures, plasma enhanced atomic layer deposition (PEALD) procedures, and/or plasma enhanced chemical vapor deposition (PECVD) procedures. Evaluation procedures and/or inspection procedures can be used to measure and/or inspect one or more surfaces of the substrates.

The P-H subsystem 150 can comprise one or more transfer/storage elements 152, one or more curing/hardening elements 153, one or more controllers 154, and one or more evaluation elements 155. One or more of the transfer/storage elements 152 can be coupled to one or more of the curing/hardening elements 153 and/or to one or more of the evaluation elements 155 and can be coupled 151 to the transfer subsystem 170. The transfer subsystem 170 can be coupled 151 to the P-H subsystem 150, and one or more substrates 105 can be transferred via coupling 151 between the transfer subsystem 170 and the P-H subsystem 150 in real time. For example, the transfer subsystem 170 can be coupled to one or more of the transfer/storage elements 152, to one or more of the curing/hardening elements 153, and/or to one or more of the evaluation elements 155. One or more of the controllers 154 can be coupled to one or more of the transfer/storage elements 152, to the one or more of the curing/hardening elements 153, and/or to one or more of the evaluation elements 155.

The evaluation subsystem 160 can comprise one or more transfer/storage elements 162, one or more measuring elements 163, one or more controllers 164, and one or more inspection elements 165. One or more of the transfer/storage elements 162 can be coupled to one or more of the measuring elements 163 and/or to one or more of the inspection elements 165 and can be coupled 161 to the transfer subsystem 170. The transfer subsystem 170 can be coupled 161 to the evaluation subsystem 160, and one or more substrates 105 can be transferred via coupling 161 between the transfer subsystem 170 and the evaluation subsystem 160 in real time. For example, the transfer subsystem 170 can be coupled to one or more of the transfer/storage elements 162, to one or more of the measuring elements 163, and/or to one or more of the inspection elements 165. One or more of the controllers 164 can be coupled to one or more of the transfer/storage elements 162, to the one or more of the measuring elements 163, and/or to one or more of the inspection elements 165. The evaluation subsystem 160 can comprise one or more measuring elements 163 that can be used to perform real-time optical evaluation procedures that can be used to measure target structures at one or more sites on a substrate using library-based or regression-based techniques. For example, the sites on substrate can include MLMIMO sites, target sites, overlay sites, alignment sites, measurement sites, verification sites, inspection sites, or damage-assessment sites, or any combination thereof. For example, one or more “golden substrates” or reference chips can be stored and used periodically to verify the performance of one or more of the measuring elements 163, and/or one or more of the inspection elements 165.

In some embodiments, the evaluation subsystem 160 can include an integrated Optical Digital Profilometry (iODP) elements (not shown), and iODP elements/systems are available from Timbre Technologies Inc. (a TEL company). Alternatively, other metrology systems and/or inspection systems may be used. For example, iODP techniques can be used to obtain real-time data that can include critical dimension (CD) data, gate structure data, and thickness data, and the wavelength ranges for the iODP data can range from less than approximately 200 nm to greater than approximately 900 nm. Exemplary iODP elements can include ODP Profiler Library elements, Profiler Application Server (PAS) elements, and ODP Profiler Software elements. The ODP Profiler Library elements can comprise application specific database elements of optical spectra and its corresponding semiconductor profiles, CDs, and film thicknesses. The PAS elements can comprise at least one computer that connects with optical hardware and computer network. The PAS elements can be configured to provide the data communication, ODP library operation, measurement process, results generation, results analysis, and results output. The ODP Profiler Software elements can include the software installed on PAS elements to manage measurement recipe, ODP Profiler library elements, ODP Profiler data, ODP Profiler search/match results, ODP Profiler calculation/analysis results, data communication, and PAS interface to various metrology elements and computer network.

The evaluation subsystem 160 can use polarizing reflectometry, spectroscopic ellipsometry, reflectometry, or other optical measurement techniques to measure accurate device profiles, accurate CDs, and multiple layer film thickness of a substrate. The integrated metrology process (iODP) can be executed as an integrated process in an integrated group of subsystems. In addition, the integrated process eliminates the need to break the substrate for performing the analyses or waiting for long periods for data from external systems. iODP techniques can be used with the existing thin film metrology systems for inline profile and CD measurement, and can be integrated with TEL processing systems and/or lithography systems to provide real-time process monitoring and control. Simulated metrology data can be generated by applying Maxwell's equations and using a numerical analysis technique to solve Maxwell's equations.

The transfer subsystem 170 can comprise transfer elements 174 coupled to transfer tracks (175, 176, and 177) that can be used to receive substrates, transfer substrates, align substrates, store substrates, and/or delay substrates. For example, the transfer elements 174 can support two or more substrates. Alternatively, other transferring means may be used. The transfer subsystem 170 can load, transfer, store, and/or unload substrates based on a P-H procedure, a P-H-related processing sequence, a transfer sequence, operational states, the substrate and/or processing states, the processing time, the current time, the substrate data, the number of sites on the substrate, the type of sites on the substrates, the number of required sites, the number of completed sites, the number of remaining sites, or confidence data, or any combination thereof.

In some examples, transfer subsystem 170 can use loading data to determine where and when to transfer a substrate. In other examples, a transfer system can use MLMIMO modeling data to determine where and when to transfer a substrate. Alternatively, other procedures may be used. For example, when the first number of substrates is less than or equal to the first number of available processing elements, the first number of substrates can be transferred to the first number of available processing elements in the one or more of the subsystems using the transfer subsystem 170. When the first number of substrates is greater than the first number of available processing elements, some of the substrates can be stored and/or delayed using one or more of the transfer/storage elements (112, 122, 132, 142, 152, and 162) and/or the transfer subsystem 170.

In addition, the one or more subsystems (110, 120, 130, 140, 150, 160, and 170) can be used when performing lithography-related procedures, scanner-related procedures, inspection-related procedures, measurement-related procedures, evaluation-related procedures, etch-related procedures, deposition-related procedures, thermal processing procedures, coating-related procedures, alignment-related procedures, polishing-related procedures, storage-related procedures, transfer procedures, cleaning-related procedures, rework-related procedures, oxidation-related procedures, nitridation-related procedures, or external processing elements, or any combination thereof.

Operational state data can be established for the subsystems (110, 120, 130, 140, 150, 160, and 170) and can be used and/or updated by the P-H procedures. In addition, operational state data can be established for the transfer/storage elements (112, 122, 132, 142, 152, and 162), elements (113, 123, 133, 143, 153, and 163), and evaluation elements (115, 125, 135, 145, 155, and 165), and can be updated by P-H procedures. For example, the operational state data for the processing elements can include availability data, matching data for the processing elements, expected processing times for some process steps and/or sites, yield data, confidence data and/or risk data for the processing elements, or confidence data and/or risk data for one or more MLMIMO-related procedures. Updated operational states can be obtained by querying in real-time one or more processing elements, and/or one or more subsystems. Updated loading data can be obtained by querying in real-time one or more transfer elements, and/or one or more transfer subsystems.

One or more of the controllers (114, 124, 134, 144, 154, and 164) can be coupled to the system controller 190 and/or to each other using a data transfer subsystem 191. Alternatively, other coupling configurations may be used. The controllers can be coupled in series and/or in parallel and can have one or more input ports and/or one or more output ports. For example, the controllers may include microprocessors having one or more core processing elements.

In addition, subsystems (110, 120, 130, 140, 150, 160, and 170) can be coupled to each other and to other devices using intranet, internet, wired, and/or wireless connections. The controllers (114, 124, 134, 144, and 190) can be coupled to external devices as required.

One or more of the controllers (114, 124, 134, 144, 154, 164, and 190) can be used when performing real-time P-H-related procedures. A controller can receive real-time data from a P-H-related model to update subsystem, processing element, process, recipe, profile, image, pattern, simulation, sequence data, and/or model data. One or more of the controllers (114, 124, 134, 144, 154, 164, and 190) can be used to exchange one or more Semiconductor Equipment Communications Standard (SECS) messages with the Manufacturing Execution Systems (MES) 180 or other systems (not shown), read and/or remove information, feed forward, and/or feedback the information, and/or send information as a SECS message. One or more of the formatted messages can be exchanged between controllers, and the controllers can process messages and extract new data in real-time. When new data is available, the new data can be used in real-time to update a model and/or procedure currently being used for the substrate and/or lot. For example, the current layout can be examined using the updated model and/or procedure when the model and/or procedure can be updated before the current layout is examined. The current layout can be examined using a non-updated model and/or procedure when an update cannot be performed before the current layout is processed. In addition, formatted messages can be used when resists are changed, when resist models are changed, when processing sequences are changed, when design rules are changed, or when layouts are changed,

In some examples, the MES 180 may be configured to monitor some subsystem and/or system processes in real-time, and factory level intervention and/or judgment rules can be used to determine which processes are monitored and which data can be used. For example, factory level intervention and/or judgment rules can be used to determine how to manage the data when a P-H-related error condition occurs. The MES 180 can also provide modeling data, processing sequence data, and/or substrate data.

In addition, controllers (114, 124, 134, 144, 154, 164, and 190) can include memory (not shown) as required. For example, the memory (not shown) can be used for storing information and instructions to be executed by the controllers, and may be used for storing temporary variables or other intermediate information during the execution of instructions by the various computers/processors in the processing system 100. One or more of the controllers (114, 124, 134, 144, 154, 164, and 190), or other system components can comprise the means for reading data and/or instructions from a computer readable medium and can comprise the means for writing data and/or instructions to a computer readable medium.

The processing system 100 can perform a portion of or all of the processing steps of the invention in response to the computers/processors in the processing system executing one or more sequences of one or more instructions contained in a memory and/or received in a message. Such instructions may be received from another computer, a computer readable medium, or a network connection.

In some embodiments, an integrated system can be configured using system components from Tokyo Electron Limited (TEL), and external subsystems and/or tools may be included. For example, measurement elements can be provided that can include a CD-Scanning Electron Microscopy (CDSEM) system, a Transmission Electron Microscopy (TEM) system, a focused ion beam (FIB) system, an Optical Digital Profilometry (ODP) system, an Atomic Force Microscope (AFM) system, or another inspection system. The subsystems and/or processing elements can have different interface requirements, and the controllers can be configured to satisfy these different interface requirements.

One or more of the subsystems (110, 120, 130, 140, 150, 160, and 170) can perform control applications, Graphical User Interface (GUI) applications, and/or database applications. In addition, one or more of the subsystems (110, 120, 130, 140, 150, 160, and 170) and/or controllers (114, 124, 134, 144, 154, 164, and 190) can include Design of Experiment (DOE) applications, Advanced Process Control (APC) applications, Fault Detection and Classification (FDC) applications, and/or Run-to-Run (R2R) applications.

Output data and/or messages from P-H procedures can be used in subsequent procedures to optimize the process accuracy and precision. Data can be passed to P-H procedures in real-time as real-time variable parameters, overriding current model values, and reducing DOE tables. Real-time data can be used with a library-based system, or regression-based system, or any combination thereof to optimize a P-H procedure.

When a library-based process is used, a P-H-related library can be generated and/or enhanced using P-H procedures, recipes, profiles, and/or models. For example, a P-H-related library can comprise simulated and/or measured P-H-related data and corresponding sets of processing sequence data. The library-based processes can be performed in real-time. An alternative procedure for generating data for a P-H-related library can include using a machine learning system (MLS). For example, prior to generating the P-H-related library data, the MLS can be trained using known input and output data, and the MLS may be trained with a subset of the P-H-related library data.

P-H procedures can include intervention and/or judgment rules that can be executed whenever a matching context is encountered. Intervention and/or judgment rules and/or limits can be established based on historical procedures, on the customer's experience, or process knowledge, or obtained from a host computer. Rules can be used in Fault Detection and Classification (FDC) procedures to determine how to respond to alarm conditions, error conditions, fault conditions, and/or warning conditions. The rule-based FDC procedures can prioritize and/or classify faults, predict system performance, predict preventative maintenance schedules, decrease maintenance downtime, and extend the service life of consumable parts in the system. Various actions can take place in response to an alarm/fault, and the actions taken on the alarm/fault can be context-based, and the context data can be specified by a rule, a system/process recipe, a chamber type, identification number, load port number, cassette number, lot number, control job ID, process job ID, slot number and/or the type of data.

Unsuccessful P-H procedures can report a failure when a limit is exceeded, and successful procedures can create warning messages when limits are being approached. Pre-specified failure actions for procedures errors can be stored in a database, and can be retrieved from the database when an error occurs. For example, P-H procedures can reject the data at one or more of the sites for a substrate when a measurement procedure fails.

P-H procedures can be used to create, modify, and/or evaluate isolated and/or nested structures at different times and/or sites. For example, gate stack dimensions and substrate thickness data can be different near isolated and/or nested structures, and gate stack dimensions and substrate thickness data can be different near open areas and/or trench array areas. The hardened photoresist features created by the P-H procedure can subsequently be used to create optimized features and/or structures for etched isolated and/or nested structures.

The P-H procedures can be used to reinforce the photo-resist film, supply optimum polymers, and suppress dissociation of the process gas. Therefore, the surface roughness of the photo-resist can be decreased. Further, the CD of an opening portion formed in the photo-resist film can be prevented from expanding, thereby realizing pattern formation with high accuracy. Particularly, these effects are more enhanced by controlling the DC voltage to suitably exercise the three functions described herein, i.e., the sputtering function, plasma optimizing function, and electron supply function.

The amount of by-products deposited during a P-H procedure depends on the potential difference between the plasma and the DC electrode, chamber wall, or the like. Accordingly, deposition of by-products can be suppressed by controlling the plasma potential, and the voltage applied from the multi-output supply system to the DC electrode can be controlled to lower the plasma potential. The plasma potential Vₚ is preferably set at a value within a range of negative 100 to negative 3000 volts.

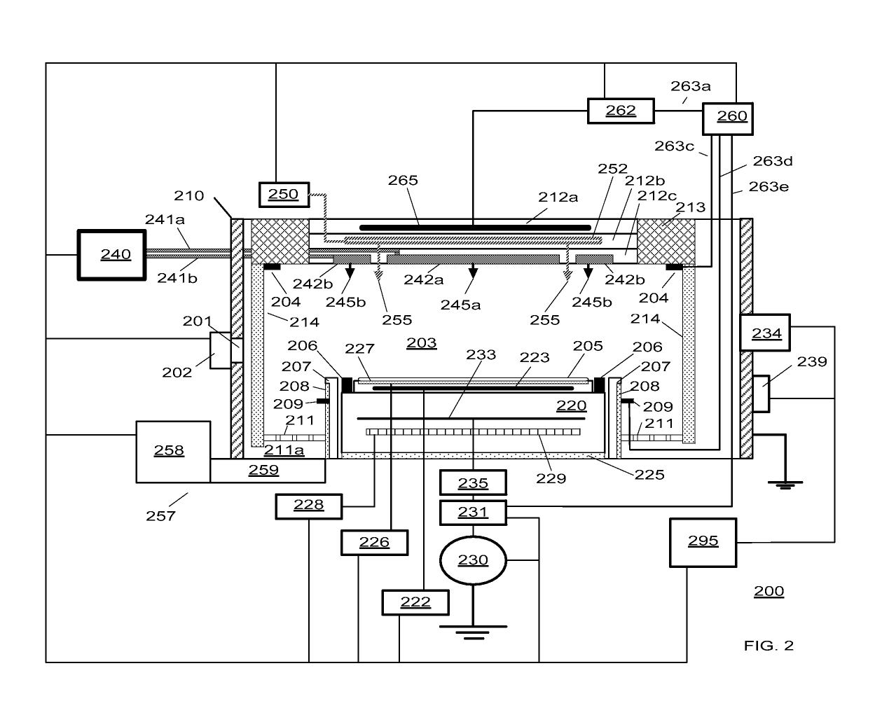

FIG. 2 shows an exemplary block diagram of an additional Photoresist-Hardening (P-H) subsystem in accordance with embodiments of the invention. A first exemplary P-H subsystem 200 is shown in FIG. 2, and the illustrated P-H subsystem 200 includes P-H chamber 210, insulating member 213, substrate holder 220, upon which a substrate 205 to be processed is affixed, gas supply system 240, remote plasma system 250, pressure control system 257, and multi-output supply system 260. Controller 295 can be used to control the gas supply system 240, the remote plasma system 250, the pressure control system 257, and the multi-output supply system 260. The multi-output supply system 260 can be coupled to an upper DC electrode 265 configured in a first upper assembly 212a. The remote plasma system 250 can be coupled to a remote plasma injection plenum 252 configured in a second upper assembly 212b, and the remote plasma injection plenum 252 can have a plurality of flow channels 255 therein. The gas supply system 240 can be coupled to the split gas injection plenums (242a and 242b) configured in a third upper assembly 212c. The inner gas injection plenum 242a can have a plurality of inner orifices 245a therein, and the outer gas injection plenum 242b can have a plurality of outer orifices 245b therein.

For example, the DC voltage applied to the upper electrode 265 by the multi-output supply system 260 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage.

The substrate holder 220 can be coupled to the P-H chamber 210 using an isolation means 225. Alternatively, the isolation means 225 may not be required. Substrate 205 can be, for example, a semiconductor substrate, a work piece, or a liquid crystal display (LCD). The P-H chamber 210 can be configured to facilitate the generation of curing plasma in processing region 203 adjacent a surface of substrate 205 using a remote plasma system 250 that can provide one or more remote plasma species. In addition, one or more ionizable gasses or mixture of gases can be introduced from gas supply system 240, and chamber pressure can be adjusted using pressure control system 257.

A transfer port 201 for a semiconductor substrate is formed in the sidewall of the P-H chamber 210, and can be opened/closed by a gate valve 202 attached thereon. Controller can be coupled to gate valve 202 and can be configured to control gate valve 202. Substrate 205 can be, for example, transferred into and out of P-H chamber 210 through transfer port 201 and gate valve 202 from a transfer subsystem (170, FIG. 1), and it can be received by substrate lift pins (not shown) housed within substrate holder 220 and mechanically translated by devices (not show) housed therein. After the substrate 205 is received from transfer system, it is lowered to an upper surface of substrate holder 220. The design and implementation of substrate lift pins is well known to those skilled in the art.

The substrate 205 can be affixed to the substrate holder 220 via an electrostatic clamping system (222, 223). The substrate holder 220 can further include temperature control elements 229 coupled to a temperature control system 228. In addition, gas can be delivered to the backside of the substrate via a dual (center/edge) backside gas elements 227 coupled to a backside gas system 226 to improve the gas-gap thermal conductance between substrate 205 and substrate holder 220. Dual (center/edge) backside gas elements 227 can be utilized when additional temperature control of the substrate is required at elevated or reduced temperatures. For example, temperature control elements 229 can include cooling elements, resistive heating elements, or thermoelectric heaters/coolers.

A conductive focus ring 206 can include a silicon-containing material and can be disposed on the top of the substrate holder 220. In some examples, conductive focus ring 206 can be configured to surround the electrostatic chuck electrode 223, the backside gas elements 227, and the substrate 205 to improve uniformity at the edge of the substrate. In other examples, the conductive focus ring 206 can include a correction ring portion (not shown) that can be used to modify the edge temperature of the substrates 205. Alternatively, a non-conductive focus ring may be used.

In some embodiments, one or more remote plasma species can be introduced to one or more areas of the processing region 203 from the remote plasma system 250 using a plurality of flow channels 255 in the remote plasma injection plenum 252. The remote plasma species can include Argon (Ar), CF₄, F₂, C₄F₈, CO, C₅F₈, C₄F₆, CHF₃, N₂/H₂, or HBr, or any combination of two or more thereof. The plurality of flow channels 255 in the remote plasma injection plenum 252 can provide different flow rates for the remote plasma species to different regions of the processing region 203. In addition, the plurality of flow channels 255 in the remote plasma injection plenum 252 can be configured to provide different remote plasma species to different regions of the processing region 203.

In addition, one or more process gasses can be introduced into one or more areas of the processing region 203 from the gas supply system 240 using the plurality of inner orifices 245a in the inner gas injection plenum 242a and the plurality of outer orifices 245b in the outer gas injection plenum 242b. The process gas can include Argon (Ar), CF₄, F₂, C₄F₈, CO, C₅F₈, C₄F₆, CHF₃, N₂/H₂, or HBr, or any combination of two or more thereof. Gas supply system 240 can be coupled to a split gas injection plenums (242a and 242b) using supply lines (241a and 241b) that are configured to reduce or minimize the introduction of contaminants to substrate 205. The split gas injection plenum (242a and 242b) can include flow control devices (not shown). For example, process gas can be supplied from a gas supply system 240 using supply lines (241a and 241b). The plurality of inner orifices 245a in the inner gas injection plenum 242a and the plurality of outer orifices 245b in the outer gas injection plenum 242b can provide different flow rates to different regions of the processing region 203. In addition, the plurality of inner orifices 245a in the inner gas injection plenum 242a and the plurality of outer orifices 245b in the outer gas injection plenum 242b can be configured to provide different process gasses to different regions of the processing region 203.

An outer deposition shield 214 can be detachably coupled along the inner wall of the P-H chamber 210 to prevent by-products created during curing procedures from being deposited on the wall. For example, the outer deposition shield 214 can be configured as a chamber wall. An inner deposition shield 208 can be detachably coupled to the substrate holder 220 to prevent by-products created during curing procedures from being deposited on the substrate holder 220.

The pressure control system 257 can include a turbo-molecular vacuum pump (TMP) 258 and a gate valve 259 for controlling the chamber pressure. For example, TMPs are useful for low pressure processing, typically less than 50 mTorr. At higher pressures, a mechanical booster pump and dry roughing pump can be used. For example, intrinsic sensors 239 can include a Type 628B Baratron absolute capacitance manometer commercially available from MKS Instruments, Inc. (Andover, Mass.) for monitoring chamber pressure.

An exhaust plate 211 can be configured at the bottom of the P-H chamber 210 and can be located between the outer deposition shield 214 on the chamber wall and the inner deposition shield 208 on the inner wall member 207. The deposition shields (208 and 214) and exhaust plate 211 can include an aluminum body covered with a ceramic, such as Y₂O₃. An exhaust space 211a can be formed at the bottom of the P-H chamber 210, and can be coupled to the gate valve 259.

As depicted in FIG. 2, the P-H subsystem 200 can include one or more intrinsic sensors 239 coupled to P-H chamber 210 to obtain performance data, and controller 295 can be coupled to the intrinsic sensors 239 to receive performance data. The intrinsic sensors 239 can include those sensors pertaining to the functionality of P-H chamber 210, such as the measurement of the Helium backside gas pressure, Helium backside flow, electrostatic clamping (ESC) voltage, ESC current, substrate holder 220 temperature (or lower electrode (LEL) temperature), coolant temperature, upper electrode (UEL) temperature, forward RF power, reflected RF power, RF self-induced DC bias, RF peak-to-peak voltage, chamber wall temperature, process gas flow rates, process gas partial pressures, matching network settings, a focus ring thickness, RF hours, focus ring RF hours, and any statistic thereof.

The P-H subsystem 200 can include one or more extrinsic sensors 234 that can include one or more optical devices for monitoring the light emitted from the plasma in processing region 203 as shown in FIG. 2, and/or one or more gas sensing devices for monitoring exhaust gasses. The sensors 234 can include an optical sensor that can be used as an End Point Detector (EPD) and can provide EPD data. For example, an Optical Emission Spectroscopy (OES) sensor may be used. In addition, the extrinsic sensors 234 can include current and/or voltage probes, power meters, spectrum analyzers, or an RF Impedance analyzer, or any combination thereof. Furthermore, the measurement of an electrical signal, such as a time trace of voltage or current, permits the transformation of the signal into frequency domain using discrete Fourier series representation (assuming a periodic signal). Thereafter, the Fourier spectrum (or for a time varying signal, the frequency spectrum) can be monitored and analyzed to characterize the state of a plasma. In alternate embodiments, extrinsic sensors 234 can include a broadband RF antenna useful for measuring a radiated RF field external to P-H chamber 210.

The P-H subsystem 200 can include a multi-output supply system 260 coupled to the upper DC electrode 265. In addition, when a DC voltage is applied to the DC electrode 265, electrons may accumulate on the DC electrode 265, and abnormal electric discharges may occur between the DC electrode 265 and the inner wall of the P-H chamber 210. In various exemplary configurations, one or more conductive elements (204, 209) can be used to provide a DC ground and to suppress the abnormal electric discharges. One or more first conductive elements 204 can be coupled to the deposition shield 214 that can be configured as a chamber wall, and one or more second conductive elements 209 can be coupled to the deposition shield 208 that can also be configured as a chamber wall. The conductive elements (204, 209) can be positioned such that they can be exposed to the curing plasma when it is created.

The first conductive element 204 can be coupled to the multi-output supply system 260 using signal line 263c. In some embodiments, the multi-output supply system 260 can use signal line 263c to connect the first conductive element 204 to ground. In other embodiments, the multi-output supply system 260 can use signal line 263c to provide a negative voltage to the first conductive element 204. In still other embodiments, the multi-output supply system 260 can use signal line 263c to provide a positive voltage to the first conductive element 204. In additional embodiments, the multi-output supply system 260 can use signal line 263c to float (disconnect) the first conductive element 204.

The second conductive element 209 can be coupled to the multi-output supply system 260 using signal line 263d. In some embodiments, the multi-output supply system 260 can use signal line 263d to connect the second conductive element 209 to ground. In other embodiments, the multi-output supply system 260 can use signal line 263d to provide a negative voltage to the second conductive element 209. In still other embodiments, the multi-output supply system 260 can use signal line 263d to provide a positive voltage to the second conductive element 209. In additional embodiments, the multi-output supply system 260 can use signal line 263d to float (disconnect) the second conductive element 209.

When the first conductive element 204 is connected to ground through signal line 263c, the DC current applied from the multi-output supply system 260 to the DC electrode 265 can flow through the processing region 203 through the first conductive element 204 to ground. When the second conductive element 209 is connected to ground through signal line 263d, the DC current applied from the multi-output supply system 260 to the DC electrode 265 can flow through the processing region 203 through the second conductive element 209 to ground. The first conductive element 204 and/or the second conductive element 209 can include silicon-containing material and/or carbon-containing material. For example, the first conductive element 204 and/or the second conductive element 209 may include Si or SiC. The first conductive element 204 and/or the second conductive element 209 can be used to allow electrons accumulated in the DC electrode 265 to be released, thereby preventing an abnormal electric discharge. One or more first conductive element 204 can be mounted around the upper electrode 265 and can have protruding lengths of 10 mm or more. One or more second conductive element 209 can be mounted around the substrate holder 220 and can have protruding lengths of 10 mm or more.

When a cleaning procedure is performed, a negative voltage can be applied to the first conductive element 204 and/or the second conductive element 209 from the multi-output supply system 260 during a cleaning procedure.

As shown in FIG. 2, substrate holder 220 includes a lower electrode 233 through which low frequency power can be coupled to plasma in processing region 203. For example, lower electrode 233 can be electrically biased at an AC voltage via the transmission of low frequency power from the low frequency generator 230 through matching network 231 to lower electrode 233. The low frequency generator 230 power can vary from approximately 10 watts to approximately 1000 watts during the P-H procedure. The low frequency power can serve to heat electrons to maintain plasma. The low frequency generator 230 frequency can range from about 10 Hz to about 100 kHz, and the operating frequency is preferably 60 Hz. Furthermore, matching network 231 serves to maximize the transfer of AC power to plasma in P-H chamber 210 by minimizing the reflected power. Various match network topologies and automatic control methods can be utilized.

Controller 295 can include a microprocessor, memory, and a digital I/O port (potentially including D/A and/or A/D converters) capable of generating control voltages sufficient to communicate and activate inputs to the P-H subsystem 200 as well as monitor outputs from P-H subsystem 200. As shown in FIG. 2, controller 295 can be coupled to and exchange information with gate valve 202, a clamping supply 222, backside gas delivery system 226, temperature control system 228, low frequency generator 230, matching network 231, extrinsic sensors 234, intrinsic sensors 239, gas supply system 240, remote plasma system 250, pressure control system 257, multi-output supply system 260, and low pass filter (LPF) 262. One or more programs stored in the memory can be utilized to interact with the aforementioned components of the P-H subsystem 200 according to stored process recipes.

When a curing process is performed by the P-H subsystem 200, the gate valve 202 can be opened, and a semiconductor substrate 205 to be cured is transferred into the P-H chamber 210 and placed on the substrate holder 220. The remote plasma system 250 can provide a remote plasma species and the P-H chamber 210 can be configured to use a remote plasma species to facilitate the generation of plasma in processing region 203 adjacent a surface of substrate 205. The remote plasma species can include a fluorocarbon element (CₓF_{y}), such as C₄F₈, and may contain another component, such as Ar or CO. The flow rate for the remote plasma species can be established using the curing recipe. In addition, an ionizable gas or mixture of gases can introduced from gas supply system 240, and process pressure can be adjusted using pressure control system 257. At the same time, the interior of the P-H chamber 210 can be exhausted by the vacuum pump 258, and the pressure inside the P-H chamber 210 can be to be a predetermined value within a range between about 0.1 Pa to about 150 Pa.

While the remote plasma species and the process gas is supplied into the P-H chamber 210, an AC signal can be applied from the low frequency generator 230 to the lower electrode 233 at a predetermined power level to maintain and control the curing plasma that is created in the processing region 203. For example, the AC signal may provide ion attraction to the lower electrode at one or more signal power levels. In addition, a predetermined DC voltage is applied from the multi-output supply system 260 to the upper DC electrode 265. Furthermore, another DC voltage can be applied from the clamping supply 222 to the electrostatic chuck electrode 223 to fix the semiconductor substrate on the substrate holder 220.

Radicals and ions generated in this curing plasma are used to cure the photoresist layer on the semiconductor substrate 205.

In this embodiment, when the curing plasma is thus generated, one or more DC voltages with predetermined polarities and values can be applied from the multi-output supply system 260 to the upper DC electrode 265. For example, the upper DC electrode 265 can have a self bias voltage V_{dc} on the surface that is large enough to cause a small to moderate amount of sputtering from one or more of the surfaces of the upper DC electrode 265. In other words, the application voltage from the multi-output supply system 260 is preferably controlled by the controller 295 to increase the absolute value of V_{dc} on the surface of the upper DC electrode 265. When a remote plasma species is provided by the plurality of flow channels 255 in remote plasma injection plenum 252 to the processing region 203 to generate the curing plasma, polymers may be deposited on the upper DC electrode 265. However, when a suitable DC voltage is applied from the multi-output supply system 260, polymers deposited on the surfaces of the upper DC electrode 265 can be sputtered, thereby cleaning one or more of the surfaces of the upper DC electrode 265. Further, an optimum quantity of polymers can be supplied onto the semiconductor substrate 205, thereby canceling the surface roughness of the photo-resist film. When the voltage applied from the multi-output supply system 260 is adjusted to sputter material from the body of the surfaces of the upper DC electrode 265, the sputtered electrode material can be supplied onto the surface of the semiconductor substrate 205. In this case, the photo-resist film can be provided with carbide formed on the surface, and this sputtered material can harden the photo-resist material.

When Fluorine ions are created in the curing plasma, some of the sputtered electrode material can react with the Fluorine ions and can be removed from the processing region 203, and the Fluorine ratio can be reduced in curing plasma so that the etching of the photo-resist film by the curing plasma is eliminated or reduced. When the upper DC electrode 265 includes a silicon-containing material, such as silicon or SiC, the sputtered silicon from the surface of the upper DC electrode 265 can react with polymers, so the photo-resist film is provided with SiC formed on the surface, and is made substantially harder (more etch resistant). In addition, Si is highly reactive with the Fluorine ions, and the effects described above can be enhanced. Accordingly, a silicon-containing material is preferably used as a material of the upper DC electrode 265. In addition, the applied current or applied power may be controlled in place of the applied voltage from the multi-output supply system 260. For example, the DC voltage applied to the upper DC electrode 265 can be controlled by the controller 295, so that broader plasma is established, and the voltage, current, and/or power values can be controlled.

Further, when the curing plasma is formed, electrons are generated near the upper DC electrode 265, and when a DC voltage is applied from the multi-output supply system 260 to the upper DC electrode 265 the electrons are accelerated in the vertical direction within the processing region 203 due to the potential difference between the applied DC voltage value and plasma potential. In other words, the multi-output supply system 260 can be set at a desired polarity, voltage value, and current value, to irradiate the semiconductor substrate 205 with electrons. The radiated electrons reform the composition of the mask or photo-resist film to reinforce the film. Accordingly, the applied voltage value and applied current value from the multi-output supply system 260 can be used to control the quantity of electrons generated near the upper DC electrode 265 and the acceleration voltage for accelerating the electrons toward the substrate 205, so that the photo-resist film is reinforced in a predetermined manner.

Particularly, where the photo-resist film on the semiconductor substrate 205 is an ArF resist film, the ArF resist film changes its polymer structure when it is radiated with electrons. When the composition of the ArF resist film is reformed due to the resist cross-linkage reaction, the etching resistance property of the ArF resist film increases. In addition, the surface roughness of the ArF resist film is decreased. Therefore, the applied voltage value or current value from the multi-output supply system 260 is preferably controlled by the controller 295 to enhance the etching resistance property of the photo-resist film (particularly, ArF resist film) by irradiation with electrons.

One or more sensors 234 may be disposed to detect the plasma state, so that the controller 295 can control the flow rate for the remote plasma species and the other photoresist curing recipe parameters using the detected plasma state. For example, a signal 263a can be independently controlled when it is applied to the upper DC electrode 265. In addition, one or more sensors 234 may be used to measure the plasma sheath length or the electron density.

In some configurations, the multi-output supply system 260 can superpose very short periodic pulses of the opposite polarity with the DC voltage applied to the upper DC electrode 265 to neutralize electrons.

The position of the first conductive element 204 and/or the second conductive element 209 is not limited to that shown in FIG. 2 as long as they are disposed in the plasma generation area. For example, when curing plasma is generated, ceramic coating materials, such as Y₂O₃, or a polymer coating materials may be released from the deposition shields (208, 214) and may be deposited on the first conductive element 204 and/or the second conductive element 209. When the first conductive element 204 and/or the second conductive element 209 becomes coated with non-conductive material, the DC grounding performance can degrade, and the number of maintenance times can be decreased by preventing this type of deposition. In some configurations, the first conductive element 204 and/or the second conductive element 209 can be located at a position remote from members covered with ceramic coatings, but preferably near parts made of a Si-containing substance, such as Si or quartz (SiO₂).

In some configurations, the multi-output supply system 260 can be programmed to apply a negative DC voltage to the conductive elements (204, and 209) using signal lines (263c, and 263d). For example, when a negative DC voltage is applied to the first conductive element 204 or the second conductive element 209, the deposited material can be sputtered or etched, thereby cleaning the surfaces of the first conductive element 204 and/or the second conductive element 209. In the P-H subsystem shown in FIG. 2, a signal line 263c can be configured to provide a negative voltage to the first conductive element 204 from the multi-output supply system 260. In addition, one or more second conductive elements 209 can be connected to ground to receive flow of a DC electron current generated by a negative DC voltage applied to the first conductive element 204

In the example shown in FIG. 2, although a DC voltage is applied to the first conductive element 204 and/or the second conductive element 209 during cleaning, an AC voltage may be alternatively applied. In other examples, protective cover films may be used on the first conductive element 204 and/or the second conductive element 209, and they may include a photoresist film. In still other examples, a plurality of first conductive element 204 and/or the second conductive element 209 and switches can be provided so that each conductive element (204, 209) can be switched in turn to a ground potential or a negative voltage.

In FIG. 2, the remote plasma system 250 may be operated at one of 13.56 MHz, 27 MHz, 40 MHz, 60 MHz, 80 MHz, 100 MHz, and 160 MHz, while the frequency of the low frequency generator may be between 10 Hz and 100 kHz, and they are suitably combined in accordance with a process to be performed. In other embodiments, the remote plasma system can include a microwave source.

In other additional embodiments, a multi-output supply system 260 can be connected to the upper DC electrode 265 and one of the signal lines 263e from the multi-output supply system 260 can be connected to the conductive focus ring 206 through another LPF 235 and the substrate holder 220. The signal lines (263a, 263c, 263d, and 263e) can be individually controlled by the controller 295. For example, one or more of the additional DC voltages can be applied to the a conductive focus ring 206 so that the curing rate can be modified to compensate for a decrease at the edge of the substrate 205, so as to perform photoresist curing with good planar uniformity on the substrate 205 and to increase the number “good” die obtainable from the substrate.

In some examples, the polarity of the signals provided on one or more of the signal lines (263a, 263c, 263d, and 263e) may be reversed or AC voltages may be applied. The signals provided on the signal lines (263a, 263c, 263d, and 263e) may be pulsed or modulated, such as AM modulation or FM modulation.

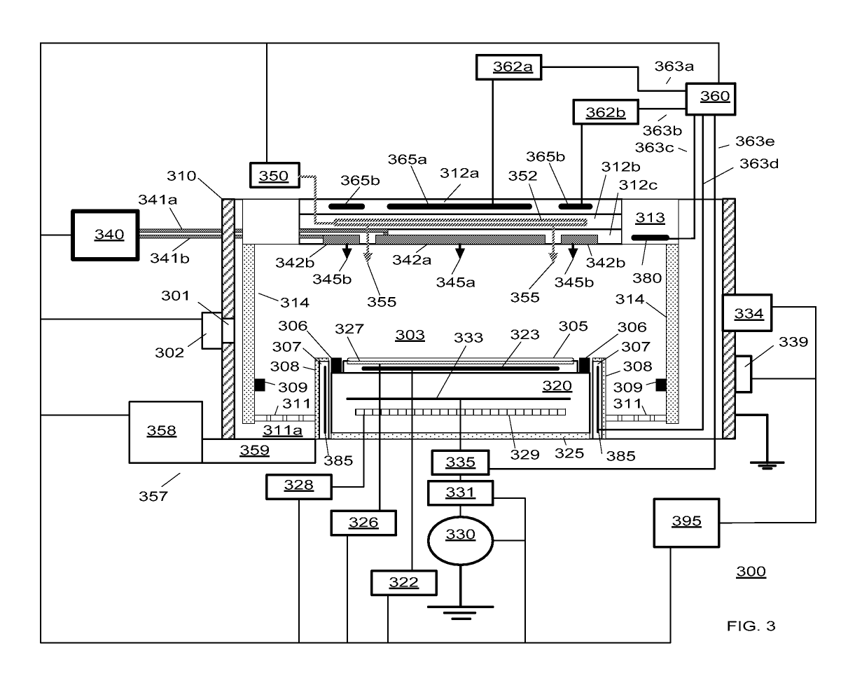

FIG. 3 shows an exemplary block diagram of an additional Photoresist-Hardening (P-H) subsystem in accordance with embodiments of the invention. A second exemplary (P-H) subsystem 300 is shown in FIG. 3, and the illustrated (P-H) subsystem 300 includes P-H chamber 310, substrate holder 320, upon which a substrate 305 to be processed is affixed, gas supply system 340, remote plasma system 350, pressure control system 357, and multi-output supply system 360. Controller 395 can be used to control the gas supply system 340, the remote plasma system 350, the pressure control system 357, and the multi-output supply system 360. The multi-output supply system 360 can be coupled to an inner DC electrode 365a and an outer DC electrode 365b configured in a first upper assembly 312a. The remote plasma system 350 can be coupled to a remote plasma injection plenum 352 configured in a second upper assembly 312b, and the remote plasma injection plenum 352 can have a plurality of flow channels 355 therein. The gas supply system 340 can be coupled to the split gas injection plenums (342a and 342b) configured in a third upper assembly 312c. The inner gas injection plenum 342a can have a plurality of inner orifices 345a therein, and the outer gas injection plenum 342b can have a plurality of outer orifices 345b therein.

For example, the DC voltage applied to the inner DC electrode 365a and the outer DC electrode 365b by the multi-output supply system 360 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage.

The substrate holder 320 can be coupled to the P-H chamber 310 using an isolation means 325. Alternatively, the isolation means 325 may not be required. Substrate 305 can be, for example, a semiconductor substrate, a work piece, or a liquid crystal display (LCD). The P-H chamber 310 can be configured to facilitate the generation of curing plasma in processing region 303 adjacent a surface of substrate 305 using one or more remote plasma species provided by one or more of the flow channels 355 in the remote plasma injection plenum 352. In addition, one or more ionizable gasses can be introduced from one or more of the inner orifices 345a in the inner gas injection plenum 342a and/or one or more of the outer orifices 345b in the outer gas injection plenum 342b, and chamber pressure can be adjusted using pressure control system 357.

A transfer port 301 for a semiconductor substrate 305 is formed in the sidewall of the P-H chamber 310, and can be opened/closed by a gate valve 302 attached thereon. Controller can be coupled to gate valve 302 and can be configured to control gate valve 302. Substrate 305 can be, for example, transferred into and out of P-H chamber 310 through transfer port 301 and gate valve 302 from a transfer subsystem (170, FIG. 1), and it can be received by substrate lift pins (not shown) housed within substrate holder 320 and mechanically translated by devices (not show) housed therein. After the substrate 305 is received from transfer system, it is lowered to an upper surface of substrate holder 320. The design and implementation of substrate lift pins is well known to those skilled in the art.

The substrate 305 can be affixed to the substrate holder 320 via an electrostatic clamping system (322, 323). The substrate holder 320 can further include temperature control elements 329 coupled to a temperature control system 328. In addition, gas can be delivered to the backside of the substrate via a dual (center/edge) backside gas elements 327 coupled to a backside gas system 326 to improve the gas-gap thermal conductance between substrate 305 and substrate holder 320. Dual (center/edge) backside gas elements 327 can be utilized when additional temperature control of the substrate is required at elevated or reduced temperatures. For example, temperature control elements 329 can include cooling elements, resistive heating elements, or thermoelectric heaters/coolers.

A conductive focus ring 306 can include a silicon-containing material and can be disposed on the top of the substrate holder 320. In some examples, conductive focus ring 306 can be configured to surround the electrostatic chuck electrode 323, the backside gas elements 327, and the substrate 305 to improve uniformity at the edge of the substrate. In other examples, the conductive focus ring 306 can include a correction ring portion (not shown) that can be used to modify the edge temperature of the substrates 305. Alternatively, a non-conductive focus ring may be used.

In some embodiments, one or more remote plasma species can be introduced to one or more areas of the processing region 303 from the remote plasma system 350 using the plurality of flow channels 355 in the remote plasma injection plenum 352. The remote plasma species can include Argon (Ar), CF₄, F₂, C₄F₈, CO, C₅F₈, C₄F₆, CHF₃, N₂H₂, or HBr, or any combination of two or more thereof. The plurality of flow channels 355 in the remote plasma injection plenum 352 can provide different flow rates for the remote plasma species to different regions of the processing region 303. In addition, the plurality of flow channels 355 in the remote plasma injection plenum 352 can be configured to provide different remote plasma species to different regions of the processing region 303.

In addition, one or more process gasses can be introduced to one or more areas of the processing region 303 using one or more of the inner orifices 345a in the inner gas injection plenum 342a and/or one or more of the outer orifices 345b in the outer gas injection plenum 342b. The process gas can include Argon (Ar), CF₄, F₂, C₄F₈, CO, C₅F₈, C₄F₆, CHF₃, N₂H₂, or HBr, or any combination of two or more thereof. Gas supply system 340 can be coupled to a split gas injection plenums (342a and 342b) using supply lines (341a and 341b) that are configured to reduce or minimize the introduction of contaminants to substrate 305. The split gas injection plenum (342a and 342b) can include flow control devices (not shown). For example, process gas can be supplied from a gas supply system 340 using supply lines (341a and 341b). One or more of the inner orifices 345a in the inner gas injection plenum 342a and/or one or more of the outer orifices 345b in the outer gas injection plenum 342b can be used to provide different flow rates to different regions of the processing region 303. In addition, one or more of the inner orifices 345a in the inner gas injection plenum 342a and/or one or more of the outer orifices 345b in the outer gas injection plenum 342b can be configured to provide different process gasses to different regions of the processing region 303.

An outer deposition shield 314 can be detachably coupled along the inner wall of the P-H chamber 310 to prevent by-products created during curing procedures from being deposited on the wall. For example, the outer deposition shield 314 can be configured as a chamber wall. An inner deposition shield 308 can be detachably coupled to the substrate holder 320 to prevent by-products created during curing procedures from being deposited on the substrate holder 320.

The pressure control system 357 can include a turbo-molecular vacuum pump (TMP) 358 and a gate valve 359 for controlling the chamber pressure. For example, TMPs are useful for low pressure processing, typically less than 50 mTorr. At higher pressures, a mechanical booster pump and dry roughing pump can be used. For example, intrinsic sensors 339 can include a Type 628B Baratron absolute capacitance manometer commercially available from MKS Instruments, Inc. (Andover, Mass.) for monitoring chamber pressure.

An exhaust plate 311 can be configured at the bottom of the P-H chamber 310 and can be located between the outer deposition shield 314 on the chamber wall and the inner deposition shield 308 on the inner wall member 307. The deposition shields (308 and 314) and exhaust plate 311 can include an aluminum body covered with a ceramic, such as Y₂O₃. An exhaust space 311a can be formed at the bottom of the P-H chamber 310, and can be coupled to the gate valve 359.

As depicted in FIG. 3, the photoresist hardening (P-H) subsystem 300 can include one or more intrinsic sensors 339 coupled to P-H chamber 310 to obtain performance data, and controller 395 can be coupled to the intrinsic sensors 339 to receive performance data. The intrinsic sensors 339 can include those sensors pertaining to the functionality of P-H chamber 310 such as the measurement of the Helium backside gas pressure, Helium backside flow, electrostatic clamping (ESC) voltage, ESC current, substrate holder 320 temperature (or lower electrode (LEL) temperature), coolant temperature, upper electrode (UEL) temperature, forward RF power, reflected RF power, RF self-induced DC bias, RF peak-to-peak voltage, chamber wall temperature, process gas flow rates, process gas partial pressures, chamber pressure, capacitor settings (i.e., C1 and C2 positions), a focus ring thickness, RF hours, focus ring RF hours, and any statistic thereof.

The photoresist hardening (P-H) subsystem 300 can include one or more extrinsic sensors 334 that can include one or more optical devices for monitoring the light emitted from the plasma in processing region 303 as shown in FIG. 3, and/or one or more gas sensing devices for monitoring exhaust gasses. The sensors 334 can include an optical sensor that can be used as an End Point Detector (EPD) and can provide EPD data. For example, an Optical Emission Spectroscopy (OES) sensor may be used. In addition, the extrinsic sensors 334 can include current and/or voltage probes, power meters, spectrum analyzers, or an RF Impedance analyzer, or any combination thereof. Furthermore, the measurement of an electrical signal, such as a time trace of voltage or current, permits the transformation of the signal into frequency domain using discrete Fourier series representation (assuming a periodic signal). Thereafter, the Fourier spectrum (or for a time varying signal, the frequency spectrum) can be monitored and analyzed to characterize the state of a plasma. In alternate embodiments, extrinsic sensors 334 can include a broadband RF antenna useful for measuring a radiated RF field external to P-H chamber 310.

In some configurations, the multi-output supply system 360 can be coupled to the inner DC electrode 365a and the outer DC electrode 365b using signal lines (363a, 363b). In addition, when a DC voltage is applied to the inner DC electrode 365a and the outer DC electrode 365b, electrons may accumulate on the inner DC electrode 365a and the outer DC electrode 365b, and abnormal electric discharges may occur between the inner DC electrode 365a and the outer DC electrode 365b and the inner wall of the P-H chamber 310. In various exemplary configurations, one or more conductive elements (380, 385) can be used to suppress the abnormal electric discharges. A first conductive element 380 can be embedded in an insulating shield member 313, and a second conductive element 385 can be embedded in another insulating shield member 308.

The first conductive element 380 can be coupled to the multi-output supply system 360 using signal line 363c. In some embodiments, the multi-output supply system 360 can use signal line 363c to connect the first conductive element 380 to ground. In other embodiments, the multi-output supply system 360 can use signal line 363c to provide a negative voltage to the first conductive element 380. In still other embodiments, the multi-output supply system 360 can use signal line 363c to provide a positive voltage to the first conductive element 380. In additional embodiments, the multi-output supply system 360 can use signal line 363c to float (disconnect) the first conductive element 380.

The second conductive element 385 can be coupled to the multi-output supply system 360 using signal line 363d. In some embodiments, the multi-output supply system 360 can use signal line 363d to connect the second conductive element 385 to ground. In other embodiments, the multi-output supply system 360 can use signal line 363d to provide a negative voltage to the second conductive element 385. In still other embodiments, the multi-output supply system 360 can use signal line 363d to provide a positive voltage to the second conductive element 385. In additional embodiments, the multi-output supply system 360 can use signal line 363d to float (disconnect) the second conductive element 385.

When the first conductive element 380 is connected to ground through signal line 363c, the DC current applied from the multi-output supply system 360 to the inner DC electrode 365a and/or the outer DC electrode 365b can flow through the processing region 303 through the first conductive element 380 to ground. When the second conductive element 385 is connected to ground through signal line 363d, the DC current applied from the multi-output supply system 360 to the inner DC electrode 365a and/or the outer DC electrode 365b can flow through the processing region 303 through the second conductive element 385 to ground. The first conductive element 380 and/or the second conductive element 385 can include silicon-containing material and/or carbon-containing material. For example, the first conductive element 380 and/or the second conductive element 385 may include Si or SiC. The first conductive element 380 and/or the second conductive element 385 can be used to allow electrons accumulated in the inner DC electrode 365a and the outer DC electrode 365b to be released, thereby preventing an abnormal electric discharge. The first conductive element 380 can have a length of 10 mm or more, and the second conductive element 385 can also have a length of 10 mm or more.

When a cleaning procedure is performed, a negative voltage can be applied to the first conductive element 380 and/or the second conductive element 385 from the multi-output supply system 360 during a cleaning procedure.

As shown in FIG. 3, substrate holder 320 includes a lower electrode 333 through which low frequency power can be coupled to plasma in processing region 303. For example, lower electrode 333 can be electrically biased at an AC voltage via the transmission of low frequency power from the low frequency generator 330 through matching network 331 to lower electrode 333. The low frequency generator 330 power can vary from approximately 10 watts to approximately 1000 watts during the P-H procedure. The low frequency power can serve to heat electrons to maintain the curing plasma. The low frequency generator 330 frequency can range from about 10 Hz to about 100 kHz, and the operating frequency is preferably 60 Hz. Furthermore, matching network 331 serves to maximize the transfer of AC power to plasma in P-H chamber 310 by minimizing the reflected power. Various match network topologies and automatic control methods can be utilized.

Controller 395 can include a microprocessor, memory, and a digital I/O port (potentially including D/A and/or A/D converters) capable of generating control voltages sufficient to communicate and activate inputs to the P-H subsystem 300 as well as monitor outputs from P-H subsystem 300. As shown in FIG. 3, controller 395 can be coupled to and exchange information with gate valve 302, clamping supply 322, backside gas delivery system 326, temperature control system 328, low frequency generator 330, matching network 331, extrinsic sensors 334, intrinsic sensors 339, gas supply system 340, remote plasma system 350, pressure control system 357, and multi-output supply system 360. One or more programs stored in the memory can be utilized to interact with the aforementioned components of the P-H subsystem 300 according to stored process recipes.

When a curing process is performed by the P-H subsystem 300, the gate valve 302 can be opened, and a semiconductor substrate 305 to be cured is transferred into the P-H chamber 310 and placed on the substrate holder 320. The remote plasma system 350 can provide a remote plasma species and the P-H chamber 310 can be configured to use a remote plasma species to facilitate the generation of plasma in processing region 303 adjacent a surface of substrate 305. The remote plasma species can include a fluorocarbon element (CₓF_{y}), such as C₄F₈, and may contain another component, such as Ar or CO. The flow rate for the remote plasma species into the processing region 303 can be established based on the curing recipe. In addition, an ionizable gas can introduced from gas supply system 340, and process pressure can be adjusted using pressure control system 357. At the same time, the interior of the P-H chamber 310 can be exhausted by the vacuum pump 358, and the pressure inside the P-H chamber 310 can be to be a predetermined value within a range between about 0.1 Pa to about 150 Pa.

While the remote plasma species and the process gas is supplied into the P-H chamber 310, an AC signal can be applied from the low frequency generator 330 to the lower electrode 333 at a predetermined power level to maintain and control the curing plasma that is created in the processing region 303. For example, the AC signal may provide ion attraction to the lower electrode at one or more signal power levels. In addition, a predetermined DC voltage can be applied from the multi-output supply system 360 to the inner DC electrode 365a and the outer DC electrode 365b. Furthermore, another DC voltage can be applied from the clamping supply 322 to the electrostatic chuck electrode 323 to fix the semiconductor substrate on the substrate holder 320.

Radicals and ions generated in this curing plasma are used to cure the photoresist layer on the semiconductor substrate 305.

In this embodiment, when the curing plasma is thus generated, one or more DC voltages with predetermined polarities and values can be applied from the multi-output supply system 360 to the inner DC electrode 365a and the outer DC electrode 365b. For example, the inner DC electrode 365a and the outer DC electrode 365b can have self bias voltages V_{dc} on the surfaces that are large enough to cause a small to moderate amount of sputtering from one or more of the surfaces of the inner DC electrode 365a and the outer DC electrode 365b. In other words, the application voltage from the multi-output supply system 360 is preferably controlled by the controller 395 to increase the absolute value of V_{dc} on the surfaces of the inner DC electrode 365a and the outer DC electrode 365b. When a remote plasma species is provided by the plurality of flow channels 355 in the remote plasma injection plenum 352 to the processing region 303 to generate the curing plasma, polymers may be deposited on the inner DC electrode 365a and the outer DC electrode 365b. However, when a suitable DC voltage is applied from the multi-output supply system 360, polymers deposited on the surfaces of the inner DC electrode 365a and the outer DC electrode 365b can be sputtered, thereby cleaning one or more of the surfaces of the inner DC electrode 365a and the outer DC electrode 365b. Further, an optimum quantity of polymers can be supplied onto the semiconductor substrate 305, thereby canceling the surface roughness of the photo-resist film. When the voltage applied from the multi-output supply system 360 is adjusted to sputter material from the body of the surfaces of the inner DC electrode 365a and the outer DC electrode 365b, the sputtered electrode material can be supplied onto the surface of the semiconductor substrate 305. In this case, the photo-resist film can be provided with carbide formed on the surface, and this sputtered material can harden the photo-resist material.

When fluorine ions are created in the curing plasma, some of the sputtered electrode material can react with the fluorine ions and can be removed from the processing region 303. The fluorine ratio can be reduced in curing plasma to reduce or eliminate the etching of the photo-resist film by the curing plasma. When the inner DC electrode 365a and the outer DC electrode 365b include silicon-containing material, such as silicon or SiC, the sputtered silicon from the surface of the inner DC electrode 365a and the outer DC electrode 365b can react with polymers, so the photo-resist film is provided with SiC formed on the surface, and is made substantially harder (more etch resistant). In addition, Si is highly reactive with the fluorine ions, and the effects described above can be enhanced. Accordingly, a silicon-containing material is preferably used as a material of the inner DC electrode 365a and the outer DC electrode 365b. The controller 395 can determine the applied voltage, the applied current, or the applied power from the multi-output supply system 360, so that a wide uniform curing plasma is established.

Further, when the curing plasma is formed, electrons are generated near the inner DC electrode 365a and the outer DC electrode 365b and when a DC voltage is applied from the multi-output supply system 360 to the inner DC electrode 365a and the outer DC electrode 365b the electrons are accelerated in the vertical direction within the processing region 303 due to the potential difference between the applied DC voltage value and plasma potential. For example, the multi-output supply system 360 can be set at a desired polarity, voltage value, and current value, to irradiate the semiconductor substrate 305 with electrons. The radiated electrons reform the composition of the mask or photo-resist film to reinforce the film. Accordingly, the applied voltage value and applied current value from the multi-output supply system 360 can be used to control the quantity of electrons generated near the inner DC electrode 365a and the outer DC electrode 365b and the acceleration voltage for accelerating the electrons toward the substrate 305, so that the photo-resist film is reinforced in a predetermined manner.

Particularly, where the photo-resist film on the semiconductor substrate 305 is an ArF resist film, the ArF resist film changes its polymer structure when it is radiated with electrons. When the composition of the ArF resist film is reformed due to the resist cross-linkage reaction, the etching resistance property of the ArF resist film increases. In addition, the surface roughness of the ArF resist film is decreased. Therefore, the applied voltage value or current value from the multi-output supply system 360 is preferably controlled by the controller 395 to enhance the etching resistance property of the photo-resist film (particularly, ArF resist film) by irradiation with electrons.

One or more sensors 334 may be disposed to detect the plasma state, so that the controller 395 can control the flow rate for the remote plasma species and the other photoresist curing recipe parameters using the detected plasma state. For example, a signal 363a can be independently controlled when it is applied to the inner DC electrode 365a and the outer DC electrode 365b. In addition, one or more sensors 334 may be used to measure the plasma sheath length or the electron density.

In some configurations, the multi-output supply system 360 can superpose very short periodic pulses of the opposite polarity with the DC voltage applied to the inner DC electrode 365a and the outer DC electrode 365b to neutralize electrons.

The position of the first conductive element 380 and/or the second conductive element 385 is not limited to that shown in FIG. 3 as long as they are disposed near the plasma generation area. For example, when curing plasma is generated, ceramic coating materials such as Y₂O₃ or a polymer coating material may be deposited on the insulating shield member 313 and/or the inner wall member 308. When the insulating shield member 313 and/or the inner wall member 308 become coated with non-conductive material, the curing performance can degrade, and the number of maintenance times can be decreased by preventing this type of deposition.

In some configurations, the multi-output supply system 360 can be programmed to apply a negative DC voltage to the conductive elements (380, and 385) using signal lines (363c, and 363d). For example, when a negative DC voltage is applied to the first conductive element 380 or the second conductive element 385, the deposited material can be sputtered or etched from the surfaces of the insulating shield member 313 and/or the inner wall member 308, thereby cleaning the exposed surfaces of the insulating shield member 313 and/or the inner wall member 308. In the P-H subsystem shown in FIG. 3, a signal line 363c can be configured to provide a negative voltage to the first conductive element 380 from the multi-output supply system 360, and a second conductive element 385 can be connected to ground to when a negative DC voltage applied to the first conductive element 380. Alternatively, AC voltages may be applied. In other examples, a plurality of first conductive element 380 and/or the second conductive element 385 and switches can be provided so that each conductive element (380, 385) can be switched in turn to a ground potential or a negative voltage.

In FIG. 3, the remote plasma system 350 may be operated at one of 13.56 MHz, 27 MHz, 40 MHz, 60 MHz, 80 MHz, 100 MHz, and 160 MHz, while the frequency of the low frequency generator may be between 10 Hz and 100 kHz, and they are suitably combined in accordance with a process to be performed. In other embodiments, the remote plasma system 350 can include a microwave source.

In other additional curing procedures, a multi-output supply system 360 can be connected to the inner DC electrode 365a and the outer DC electrode 365b, and one of the signal lines 363e from the multi-output supply system 360 can be connected to the conductive focus ring 306 through the LPF 335. The signal lines (363a, 363b, 363c, 363d, and 363e) can be individually controlled by the controller 395. For example, one or more of the additional DC voltages can be applied to the a conductive focus ring 306 so that the curing rate can be modified to compensate for a decrease at the edge of the substrate 305, so as to perform photoresist curing with good planar uniformity on the substrate 305 and to increase the number “good” die obtainable from the substrate.

In some examples, the polarity of the signals provided on one or more of the signal lines (363a, 363b, 363c, 363d, and 363e) may be reversed or AC voltages may be applied. The signals provided on the signal lines (363a, 363b, 363c, 363d, and 363e) may be pulsed or modulated, such as AM modulation or FM modulation.

In addition, when a curing plasma is generated in the photoresist-hardening (P-H) subsystem 300, the voltages applied to the conductive elements (380, 385) can be optimized, so that ions are accelerated by the difference between the plasma potential and each of potentials penetrating the insulating shield member 313 and inner wall member 308, and deposited substances can be prevented from accumulating on the insulating shield member 313 and insulating inner wall member 308.

In still other examples, the signal lines (363c and 363d) can be configured to provide differential DC voltages to the first conductive element 380 and the second conductive element 385. In this case, signal line 363c can be coupled to a positive terminal of the multi-output supply system 360 and signal line 363d can be coupled to a negative terminal of the multi-output supply system 360. When a curing plasma is generated in the photoresist-hardening (P-H) subsystem 300 using this configuration, signal lines (363a and 363b) are not required or may be used to provide additional control signals to the inner DC electrode 365a and the outer DC electrode 365b. The signal lines (363c and 363d) from multi-output supply system 360 can be can be used to provide predetermined differential DC voltages to the conductive elements (380 and 385). In addition, the applied differential voltages can be optimized, so that ions are accelerated by the difference between the plasma potential and each of potentials penetrating the insulating shield member 313 and inner wall member 308. As a consequence, deposited substances (deposition) are prevented from accumulating on the insulating shield member 313 and insulating inner wall member 308. In alternate embodiment, the polarity of the differential voltages may be reversed, or AC voltage may be applied, and the differential voltages may be pulsed or modulated, such as AM modulation or FM modulation.

In some additional embodiments, the P-H subsystem 300 can include one or more conductive elements 309 that can be coupled to a DC ground (grounded with respect to DC). For example, one or more conductive elements can be coupled to the deposition shield 314 that can act as a conductive chamber wall. When a DC current from the inner DC electrode 365a and the outer DC electrode 365b flows through the processing region 303 to the conductive element 309, and the DC current can be sent to ground through the deposition shield 314. The conductive element 309 can include a conductive silicon-containing material such as Si or SiC. In addition, the conductive element 309 can include a carbon-containing material. The conductive element 309 allows electrons accumulated in the inner DC electrode 365a and the outer DC electrode 365b to be released, thereby preventing abnormal electric discharge. In some examples, the conductive element 309 can be configured as a ring structure with an inner diameter greater than the diameter of the substrate 305 and with widths and/or thickness of 10 mm or more. The position of the conductive element 309 is not limited to that shown in FIG. 3 as long as it is disposed in the plasma generation area.

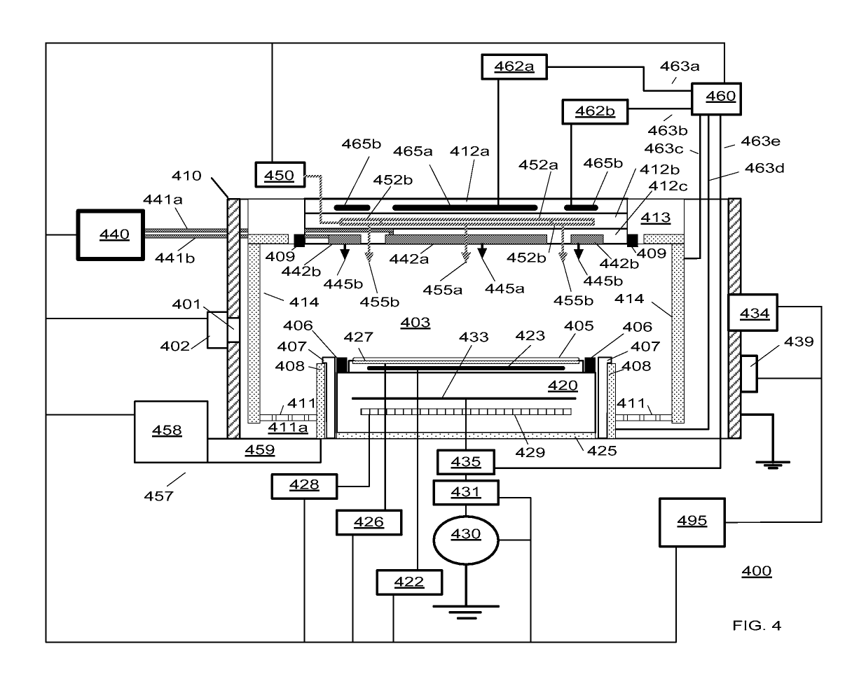

FIG. 4 shows an exemplary block diagram of another additional Photoresist-Hardening (P-H) subsystem in accordance with embodiments of the invention. A third exemplary P-H subsystem 400 is shown in FIG. 4, and the illustrated P-H subsystem 400 includes P-H chamber 410, substrate holder 420, upon which a substrate 405 to be processed is affixed, gas supply system 440, and pressure control system 457. Controller 495 can be used to control the gas supply system 440, the remote plasma system 450, the pressure control system 457, and the multi-output supply system 460. The multi-output supply system 460 can be coupled to an inner DC electrode 465a and an outer DC electrode 465b configured in a first upper assembly 412a. The remote plasma system 450 can be coupled to inner remote plasma injection plenum 452a and the outer remote plasma injection plenum 452b configured in a second upper assembly 412b. The inner remote plasma injection plenum 452a can have a plurality of inner flow channels 455a therein, and the outer remote plasma injection plenum 452b can have a plurality of outer flow channels 455b therein. The gas supply system 440 can be coupled to the inner gas injection plenum 442a and the outer gas injection plenum 442b configured in a third upper assembly 412c. The inner gas injection plenum 442a can have a plurality of inner orifices 445a therein, and the outer gas injection plenum 442b can have a plurality of outer orifices 445b therein.

For example, the DC voltage applied to the inner DC electrode 465a and the outer DC electrode 465b by multi-output supply system 460 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage.

The substrate holder 420 can be coupled to the P-H chamber 410 using an isolation means 425. Alternatively, the isolation means 425 may not be required. Substrate 405 can be, for example, a semiconductor substrate, a work piece, or a liquid crystal display (LCD). The P-H chamber 410 can be configured to facilitate the generation of curing plasma in processing region 403 adjacent a surface of substrate 405 using a remote plasma system 450 that can provide one or more remote plasma species. In addition, one or more ionizable gasses can be introduced from gas supply system 440, and chamber pressure can be adjusted using pressure control system 457.

A transfer port 401 for a semiconductor substrate is formed in the sidewall of the P-H chamber 410, and can be opened/closed by a gate valve 402 attached thereon. Controller can be coupled to gate valve 402 and can be configured to control gate valve 402. Substrate 405 can be, for example, transferred into and out of P-H chamber 410 through transfer port 401 and gate valve 402 from a transfer subsystem (170, FIG. 1), and it can be received by substrate lift pins (not shown) housed within substrate holder 420 and mechanically translated by devices (not show) housed therein. After the substrate 405 is received from transfer system, it is lowered to an upper surface of substrate holder 420. The design and implementation of substrate lift pins is well known to those skilled in the art.

The substrate 405 can be affixed to the substrate holder 420 via an electrostatic clamping system (422, 423). The substrate holder 420 can further include temperature control elements 429 coupled to a temperature control system 428. In addition, gas can be delivered to the backside of the substrate via a dual (center/edge) backside gas elements 427 coupled to a backside gas system 426 to improve the gas-gap thermal conductance between substrate 405 and substrate holder 420. Dual (center/edge) backside gas elements 427 can be utilized when additional temperature control of the substrate is required at elevated or reduced temperatures. For example, temperature control elements 429 can include cooling elements, resistive heating elements, or thermo-electric heaters/coolers.

A conductive focus ring 406 can include a silicon-containing material and can be disposed on the top of the substrate holder 420. In some examples, conductive focus ring 406 can be configured to surround the electrostatic chuck electrode 423, the backside gas elements 427, and the substrate 405 to improve uniformity at the edge of the substrate. In other examples, the conductive focus ring 406 can include a correction ring portion (not shown) that can be used to modify the edge temperature of the substrates 405. Alternatively, a non-conductive focus ring may be used.

In some embodiments, one or more remote plasma species can be introduced to one or more areas of the processing region 403 from the remote plasma system 450 using the one or more of the inner flow channels 455a in the inner remote plasma injection plenum 452a and/or one or more of the outer flow channels 455b in the outer remote plasma injection plenum 452b. The remote plasma species can include Argon (Ar), CF₄, F₂, C₄F₈, CO, C₅F₈, C₄F₆, CHF₃, N₂H₂, or HBr, or any combination of two or more thereof. One or more of the inner flow channels 455a in the inner remote plasma injection plenum 452a and/or one or more of the outer flow channels 455b in the outer remote plasma injection plenum 452b can be used to provide different flow rates for the remote plasma species to different regions of the processing region 403. In addition, one or more of the inner flow channels 455a in the inner remote plasma injection plenum 452a and/or one or more of the outer flow channels 455b in the outer remote plasma injection plenum 452b can be configured to provide different remote plasma species to different regions of the processing region 403.

In addition, one or more process gasses can be introduced to one or more areas of the processing region 403 from the gas supply system 440 using one or more of the inner orifices 445a in the inner gas injection plenum 442a and/or one or more of the outer orifices 445b in the outer gas injection plenum 442. The process gas can include Argon (Ar), CF₄, F₂, C₄F₈, CO, C₅F₈, C₄F₆, CHF₃, N₂H₂, or HBr, or any combination of two or more thereof. Gas supply system 440 can be coupled to a split gas injection plenums (442a and 442b) using supply lines (441a and 441b) that are configured to reduce or minimize the introduction of contaminants to substrate 405. The gas injection plenums (442a and 442b) can include flow control devices (not shown). For example, process gas can be supplied from a gas supply system 440 to the inner gas injection plenum 442a and to the outer gas injection plenum 442b using supply lines (441a and 441b). One or more of the inner orifices 445a in the inner gas injection plenum 442a and/or one or more of the outer orifices 445b in the outer gas injection plenum 442b can be used to provide different flow rates to different regions of the processing region 403. In addition, one or more of the inner orifices 445a in the inner gas injection plenum 442a and/or one or more of the outer orifices 445b in the outer gas injection plenum 442b can be configured to provide different process gasses to different regions of the processing region 403.

The remote plasma system 450 may be operated at one of 13.56 MHz, 27 MHz, 40 MHz, 60 MHz, 80 MHz, 100 MHz, 160 MHz, and 2.45 GHz, while the frequency of the low frequency generator may be between 10 Hz and 100 kHz, and they are suitably combined in accordance with a process to be performed.

An outer deposition shield 414 can be detachably coupled along the inner wall of the P-H chamber 410 to prevent by-products created during curing procedures from being deposited on the wall. For example, the outer deposition shield 414 can be configured as a chamber wall. An inner deposition shield 408 can be detachably coupled to the substrate holder 420 to prevent by-products created during curing procedures from being deposited on the substrate holder 420.

The pressure control system 457 can include a turbo-molecular vacuum pump (TMP) 458 and a gate valve 459 for controlling the chamber pressure. For example, TMPs are useful for low pressure processing, typically less than 50 mTorr. At higher pressures, a mechanical booster pump and dry roughing pump can be used. For example, intrinsic sensors 439 can include a Type 628B Baratron absolute capacitance manometer commercially available from MKS Instruments, Inc. (Andover, Mass.) for monitoring chamber pressure.

An exhaust plate 411 can be configured at the bottom of the P-H chamber 410 and can be located between the outer deposition shield 414 on the chamber wall and the inner deposition shield 408 on the inner wall member 407. The deposition shields (408 and 414) and exhaust plate 411 can include an aluminum body covered with a ceramic, such as Y₂O₃. An exhaust space 411a can be formed at the bottom of the P-H chamber 410, and can be coupled to the gate valve 459.

As depicted in FIG. 4, the photoresist hardening (P-H) subsystem 400 can include one or more intrinsic sensors 439 coupled to P-H chamber 410 to obtain performance data, and controller 495 can be coupled to the intrinsic sensors 439 to receive performance data. The intrinsic sensors 439 can include those sensors pertaining to the functionality of P-H chamber 410 such as the measurement of the Helium backside gas pressure, Helium backside flow, electrostatic clamping (ESC) voltage, ESC current, substrate holder 420 temperature (or lower electrode (LEL) temperature), coolant temperature, upper electrode (UEL) temperature, forward RF power, reflected RF power, RF self-induced DC bias, RF peak-to-peak voltage, chamber wall temperature, process gas flow rates, process gas partial pressures, chamber pressure, matching network settings, a focus ring thickness, RF hours, focus ring RF hours, and any statistic thereof.

The photoresist hardening (P-H) subsystem 400 can include one or more extrinsic sensors 434 that can include one or more optical devices for monitoring the light emitted from the plasma in processing region 403 as shown in FIG. 4, and/or one or more gas sensing devices for monitoring exhaust gasses. The sensors 434 can include an optical sensor that can be used as an End Point Detector (EPD) and can provide EPD data. For example, an Optical Emission Spectroscopy (OES) sensor may be used. In addition, the extrinsic sensors 434 can include current and/or voltage probes, power meters, spectrum analyzers, or an RF Impedance analyzer, or any combination thereof. Furthermore, the measurement of an electrical signal, such as a time trace of voltage or current, permits the transformation of the signal into frequency domain using discrete Fourier series representation (assuming a periodic signal). Thereafter, the Fourier spectrum (or for a time varying signal, the frequency spectrum) can be monitored and analyzed to characterize the state of a plasma. In alternate embodiments, extrinsic sensors 434 can include a broadband RF antenna useful for measuring a radiated RF field external to P-H chamber 410.

In some configurations, a multi-output supply system 460 can be coupled to the inner DC electrode 465a and the outer DC electrode 465b using signal lines (463a and 463b). In addition, when a DC voltage is applied to the inner DC electrode 465a and the outer DC electrode 465b, electrons may accumulate on the inner DC electrode 465a and the outer DC electrode 465b, and arcing may occur between the inner DC electrode 465a and the outer DC electrode 465b and the inner wall of the P-H chamber 410. In addition, two deposition shields (414 and 408) are shown, but alternatively a different number of deposition shields may be used, and they may be configured differently. The two deposition shields (414 and 408) can be insulated from each other and can be configured as a floating wall. In various exemplary configurations, the deposition shields (408 and 414) can be used to suppress and/or eliminate the arcing.

An outer deposition shield 414 can be coupled to a chamber wall using an insulating member 413, and a signal line 463c from multi-output supply system 460 can be connected to the outer deposition shield 414. In some embodiments, the multi-output supply system 460 can use signal line 463c to connect the outer deposition shield 414 to ground. In other embodiments, the multi-output supply system 460 can use signal line 463c to provide a negative voltage to the outer deposition shield 414. In still other embodiments, the multi-output supply system 460 can use signal line 463c to provide a positive voltage to the outer deposition shield 414. In additional embodiments, the multi-output supply system 460 can use signal line 463c to provide a differential signal the outer deposition shield 414.

In addition, an inner deposition shield 408 can be coupled to the substrate holder 420 using an inner wall member 407, and a signal line 463d from multi-output supply system 460 can be connected to the inner deposition shield 408. In some embodiments, the multi-output supply system 460 can use signal line 463d to connect the inner deposition shield 408 to ground. In other embodiments, the multi-output supply system 460 can use signal line 463d to provide a negative voltage to the inner deposition shield 408. In still other embodiments, the multi-output supply system 460 can use signal line 463d to provide a positive voltage to the inner deposition shield 408. In additional embodiments, the multi-output supply system 460 can use signal line 463d to provide a differential signal to the inner deposition shield 408.

When the outer deposition shield 414 is connected to ground through signal line 463c, the DC current applied from the multi-output supply system 460 to the inner DC electrode 465a and/or the outer DC electrode 465b can flow through the processing region 403 through the outer deposition shield 414 to ground. When the inner deposition shield 408 is connected to ground through signal line 463d, the DC current applied from the multi-output supply system 460 to the inner DC electrode 465a and/or the outer DC electrode 465b can flow through the processing region 403 through the inner deposition shield 408 to ground. The outer deposition shield 414 and/or the inner deposition shield 408 can include silicon-containing material and/or carbon-containing material. For example, the outer deposition shield 414 and/or the inner deposition shield 408 may include Si or SiC. The outer deposition shield 414 and/or the inner deposition shield 408 may be used to allow electrons accumulated in the inner DC electrode 465a and the outer DC electrode 465b to be released, thereby preventing an abnormal electric discharge. For example, insulating member 413 and inner wall member 407 can be configured using quartz. Alternatively, the signal lines (463c and 463d) may be routed differently.

When curing plasma is generated in the processing region 403, signal lines (463a and 463b) can be used to provide predetermined DC voltages to the inner DC electrode 465a and the outer DC electrode 465b. The signal line 463c from multi-output supply system 460 can be can be used to provide predetermined first DC voltages to the outer deposition shield 414. The signal line 463d from multi-output supply system 460 can be can be used to provide predetermined second DC voltages to the inner deposition shield 408. In addition, the applied voltages can be optimized, so that deposited substances (deposition) can be prevented from accumulating on the insulating member 413 and inner wall member 407.

Since the inner DC electrode 465a and the outer DC electrode 465b, the outer deposition shield 414 and the substrate holder 420 are isolated from the ground, the potential differences between the outer deposition shield 414 and the inner DC electrode 465a and the outer DC electrode 465b and the potential difference between the inner deposition shield 408 and the substrate holder 420 are determined by the applied signals. In this manner, arc discharge can be prevented without exposing a grounded portion to the plasma. In addition, since ions are accelerated by the potential difference between them, deposited substances (deposition) are prevented from accumulating on the deposition shields (414 and 408) by controlling these potential differences. Furthermore, the effect of confining the plasma can be obtained by optimizing the potential directions and voltages to form a potential difference in the exhaust space 411a.

In other examples, the polarity of the signals provided on one or more of the signal lines (463a, 463b, 463c, 463d, and 463e) may be reversed or AC voltages may be applied. The signals provided on the signal lines (463a, 463b, 463c, 463d, and 463e) may be pulsed or modulated, such as AM modulation or FM modulation.

In still other examples, the signal lines (463d and 463e) can be configured to provide differential DC voltages to the outer deposition shield 414 and the inner deposition shield 408. In this case, signal line 463d can be coupled to a positive terminal of the multi-output supply system 460 and signal line 463e can be coupled to a negative terminal of the multi-output supply system 460. When a curing plasma is generated in the photoresist-hardening (P-H) subsystem 400 using this configuration, signal lines (463a and 463b) are not required or may be used to provide additional control signals to the inner DC electrode 465a and the outer DC electrode 465b. The signal lines (463d and 463e) from multi-output supply system 460 can be can be used to provide predetermined differential DC voltages to the outer deposition shield 414 and the inner deposition shield 408. In addition, the applied differential voltages can be optimized, so that deposited substances (deposition) are prevented from accumulating on the outer deposition shield 414 and the inner deposition shield 408. Further, the voltages applied to the outer deposition shield 414 and the inner deposition shield 408 can be optimized to prevent electrons from spreading, thereby confining the plasma. In the configuration shown in FIG. 4, an electric field can be applied in a lateral direction to prevent the plasma from expanding downward. In alternate embodiments, the polarity of the differential voltages may be reversed, or AC voltage may be applied, and the differential voltages may be pulsed or modulated, such as AM modulation or FM modulation.

In further examples, when curing plasma is generated in the photoresist-hardening (P-H) subsystem 400 shown in FIG. 4, a cleaning procedure may not be required. When this configuration is used, signal lines (463a and 463b) are not required or may be used to provide additional control signals to the inner DC electrode 465a and the outer DC electrode 465b. The signal lines (463d and 463e) from multi-output supply system 460 can be can be used to provide a potential difference between the outer deposition shield 414 and the inner deposition shield 408 that can be used to accelerate ions, so that deposited materials are prevented from accumulating on the outer deposition shield 414 and the inner deposition shield 408. Further, an electric field can be applied in a direction perpendicular to the exhaust direction, so that ions and electrons are caused to collide with the outer deposition shield 414 and the inner deposition shield 408 and thereby confining the curing plasma.

When a curing process is performed by the P-H subsystem 400, the gate valve 402 can be opened, and a semiconductor substrate 405 to be cured is transferred into the P-H chamber 410 and placed on the substrate holder 420. The remote plasma system 450 can provide a remote plasma species and the P-H chamber 410 can be configured to use a remote plasma species to facilitate the generation of plasma in processing region 403 adjacent a surface of substrate 405. The flow rate for the remote plasma species can be established using the curing recipe. In addition, an ionizable gas or mixture of gases can introduced from gas supply system 440, and process pressure can be adjusted using pressure control system 457. For example, plasma can be used to harden and/or cure one or more photoresist layers on the substrate 405.

For example, a process gas for curing can be supplied from the gas supply system 440 into one or more of the inner orifices 445a in the inner gas injection plenum 442a and/or one or more of the outer orifices 445b in the outer gas injection plenum 442b at predetermined flow rates, and can then be supplied into the P-H chamber 410 through one or more of the inner orifices 445a in the inner gas injection plenum 442a and/or one or more of the outer orifices 445b in the outer gas injection plenum 442b. At the same time, the interior of the P-H chamber 410 can be exhausted by the vacuum pump 458, and the pressure inside the P-H chamber 410 can be to be a predetermined value within a range between about 0.1 Pa to about 150 Pa. The process gas may be selected from various gases conventionally employed for photoresist curing, and preferably is a gas containing a halogen element, a representative of which is a fluorocarbon gas (CₓF_{y}), such as C₄F₈ gas. Further, the process gas may contain another gas, such as Ar gas or CO gas.

While the remote plasma species and the resist-curing gas is supplied into the P-H chamber 410, an AC signal can be applied from the low frequency generator 430 to the lower electrode 433 at a predetermined power level to maintain and control the curing plasma that is created in the processing region 403. For example, the AC signal may provide ion attraction to the lower electrode at one or more signal power levels. In addition, predetermined DC voltages can be applied from the multi-output supply system 460 to the inner DC electrode 465a and the outer DC electrode 465b. Furthermore, another DC voltage can be applied from the clamping supply 422 to the electrostatic chuck electrode 423 to fix the semiconductor substrate on the substrate holder 420.

Radicals and ions generated in this curing plasma are used to cure the photoresist layer on the semiconductor substrate 405.

In this embodiment, when the curing plasma is thus generated, one or more DC voltages with predetermined polarities and values can be applied from the multi-output supply system 460 to the inner DC electrode 465a and the outer DC electrode 465b. For example, the inner DC electrode 465a and the outer DC electrode 465b can have self bias voltages V_{dc} on the surface that is large enough to cause a small to moderate amount of sputtering from one or more of the surfaces of the inner DC electrode 465a and the outer DC electrode 465b. For example, the application voltages from the multi-output supply system 460 can be controlled by the controller 495 to increase the absolute values of V_{dc} on the surfaces of the inner DC electrode 465a and the outer DC electrode 465b. When remote plasma species are provided by the inner flow channels 455a in the inner remote plasma injection plenum 452a and/or by the outer flow channels 455b in the outer remote plasma injection plenum 452b to the processing region 403 to generate the curing plasma, polymers may be deposited on the inner DC electrode 465a and the outer DC electrode 465b. However, when suitable DC voltages are applied from the multi-output supply system 460, polymers deposited on the surfaces of the inner DC electrode 465a and the outer DC electrode 465b can be sputtered, thereby cleaning one or more of the surfaces of the inner DC electrode 465a and the outer DC electrode 465b. Further, an optimum quantity of polymers can be supplied onto the semiconductor substrate 405, thereby canceling the surface roughness of the photo-resist film. When the voltage applied from the multi-output supply system 460 is adjusted to sputter material from the body of the surfaces of the inner DC electrode 465a and the outer DC electrode 465b, the sputtered electrode material can be supplied onto the surface of the semiconductor substrate 405. In this case, the photo-resist film can be provided with carbide formed on the surface, and this sputtered material can harden the photo-resist material.

When fluorine ions are created in the curing plasma, some of the sputtered electrode material can react with the fluorine ions and can be removed from the processing region 403. For example, the fluorine ratio can be reduced in curing plasma to reduce or eliminate the etching of the photo-resist film by the curing plasma. When the inner DC electrode 465a and the outer DC electrode 465b include silicon-containing material, such as silicon or SiC, the sputtered silicon from the surfaces of the inner DC electrode 465a and the outer DC electrode 465b can react with polymers, so the photo-resist film is provided with SiC formed on the surface, and is made substantially harder (more etch resistant). In addition, Si is highly reactive with the Fluorine ions, and the effects described above can be enhanced. Accordingly, a silicon-containing material is preferably used as a material of the inner DC electrode 465a and the outer DC electrode 465b. The controller 495 can determine the applied voltage, the applied current, and/or the applied power from the multi-output supply system 460, so that a wide uniform curing plasma is established.

Further, when the curing plasma is formed, electrons are generated near the inner DC electrode 465a and the outer DC electrode 465b, and when a DC voltages are applied from the multi-output supply system 460 to the inner DC electrode 465a and the outer DC electrode 465b the electrons can be accelerated in the vertical direction within the processing region 403 due to the potential difference between the applied DC voltage value and plasma potential. In other words, the multi-output supply system 460 can be set at a desired polarity, voltage value, and current value, to irradiate the semiconductor substrate 405 with electrons. The radiated electrons reform the composition of the mask or photo-resist film to reinforce the film. Accordingly, the applied voltage value and applied current value from the multi-output supply system 460 can be used to control the quantity of electrons generated near the inner DC electrode 465a and the outer DC electrode 465b and the acceleration voltage for accelerating the electrons toward the substrate 405, so that the photo-resist film is reinforced in a predetermined manner.

Particularly, where the photo-resist film on the semiconductor substrate 405 is an ArF resist film, the ArF resist film changes its polymer structure when it is radiated with electrons. When the composition of the ArF resist film is reformed due to the resist cross-linkage reaction, the etching resistance property of the ArF resist film increases. In addition, the surface roughness of the ArF resist film is decreased. Therefore, the applied voltage value or current value from the multi-output supply system 460 is preferably controlled by the controller 495 to enhance the etching resistance property of the photo-resist film (particularly, ArF resist film) by irradiation with electrons.

Accordingly, the applied voltage value or current value from the multi-output supply system 460 is preferably controlled by the controller 495 to enhance the etching resistance property of the photo-resist film (particularly, ArF resist film) by irradiation with electrons.

One or more sensors 434 may be disposed to detect the plasma state, so that the controller 495 can control the flow rate for the remote plasma species and the other photoresist curing recipe parameters using the detected plasma state. In addition, one or more sensors 434 may be used to measure the plasma sheath length or the electron density.

During some P-H procedures, when DC voltages are applied to the inner DC electrode 465a and the outer DC electrode 465b, electrons may accumulate on the inner DC electrode 465a and the outer DC electrode 465b and may thereby cause abnormal electric discharge between the inner DC electrode 465a and the outer DC electrode 465b and the inner wall of the photoresist-curing chamber 410. In order to suppress unwanted electrical discharges, the P-H subsystem 400 can include one or more conductive elements 409 that can be coupled to a DC ground (grounded with respect to DC). For example, one or more conductive elements 409 can be coupled to the upper assembly 412 that can act as a conductive chamber wall. When a DC current from the inner DC electrode 465a and the outer DC electrode 465b flows through the processing region 403 to the conductive element 409, and the DC current can be sent to ground through the upper assembly 412. The conductive element 409 can include a conductive silicon-containing material such as Si or SiC. In addition, the conductive element 409 can include a carbon-containing material.

The position of the conductive element 409 is not limited to that shown in FIG. 4 as long as it is disposed in the plasma generation area.

When curing plasma is generated in the P-H subsystem 400, one or more of the additional DC voltages can be applied to the conductive focus ring 406 so that the curing rate can be modified at the edge of the substrate 405. When one or more of the additional DC voltages are applied to the conductive focus ring 406, a more uniform photoresist curing can be achieved on the substrate.

In some examples, the conductive element 409 can be configured as a ring structure with an inner diameter greater than the diameter of the substrate 405 and with widths and/or thickness of 10 mm or more.

In some configurations, the Multi-output supply system 460 can superpose very short periodic pulses of the opposite polarity with the DC voltage applied to the inner DC electrode 465a and the outer DC electrode 465b to neutralize electrons.

In alternate embodiments, the photoresist hardening (P-H) subsystems described herein may further comprise either a stationary, or mechanically or electrically rotating magnetic field system (not shown), in order to potentially increase plasma density and/or improve plasma processing uniformity.

In other alternate embodiments, the photoresist hardening (P-H) subsystems described herein may further comprise one or more inductively coupled sources that may be configured in an upper portion or a central portion of the P-H chamber.

As described herein, the voltages applied to the DC electrode can be controlled to lower the plasma potential during the P-E procedure. As a consequence, curing by-products can be prevented from being deposited within the P-H chambers.

In still other embodiments not shown, the P-H subsystems may comprise one or more surface wave plasma (SWP) sources (not shown).

When the P-H subsystems (300, 400, or 400) are used to cure a photoresist layer that has been deposited over a silicon-containing film (SiC, SiN, etc.), a combination of (C₅F₈, Ar, and/or N₂), (C₄F₈, Ar, and/or N₂), (C₅F₈, Ar, N₂, and/or CO), or (C₄F₈, Ar, N₂, and/or CO) may be preferably used as a photoresist curing gas.

When the P-H subsystems (300, 400, or 400) are used to cure a photoresist layer that has been deposited over a trench structure, CF₄ or a combination of (CF₄ and Ar) or (N₂ and H₂) may be preferably used as a photoresist curing gas.

When the P-H subsystems (300, 400, or 400) are used to cure a photoresist layer that has been deposited over an organic anti-reflection film on an insulating film, CF₄ or a combination of (CF₄ and C₃F₈), (CF₄ and C₄F₈), or (CF₄ and C₄F₆) may be used as a photoresist curing gas.

When the P-H subsystems (300, 400, or 400) are used to cure a photoresist layer that has been deposited over a HARC, a combination of (C₄F₆, CF₄, Ar, and/or CO), (C₄F₆, C₃F₈, Ar, and/or CO), (C₄F₆, C₄F₈, Ar, and/or CO), (C₄F₆, C₂F₆, Ar, and/or CO), (C₄F₈, Ar, and/or CO), (C₄, F₈, Ar, and/or CO), or (C₄F₈, Ar, and/or CO) may be preferably used as a photoresist curing gas.

The photoresist curing gas is not limited to the examples described above, and another combination of (CₓH_{y}F_{z} gas/additive gas such as N₂ or O₂/dilution gas) may be used.

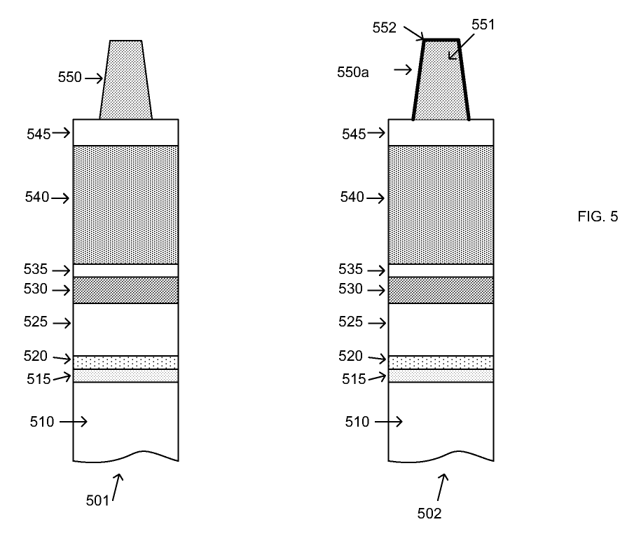

FIG. 5 illustrates an exemplary view of a first Photoresist-Hardening (P-H) procedure using a metal gate structure in accordance with embodiments of the invention. In the illustrated embodiment, two exemplary gate stacks (501 and 502) are shown, but this is not required for the invention. Alternatively, a different number of gates stacks, a different number of models, and different configurations may be used.

First gate stack 501 is shown that includes a substrate layer 510, a metal gate layer 515, a first hard mask layer 520, a first silicon-containing layer 525, a second silicon-containing layer 530, a second hard mask layer 535, a gate-width control layer 540, a third hard mask layer 545, and a pattern of soft mask features 550. For example, the substrate layer 510 can include a semiconductor material; the metal gate layer 515 can include HfO₂; the first hard mask layer 520 can include TiN; the first silicon-containing layer 525 can include amorphous silicon (a-Si); the second silicon-containing layer 530 can include SiN; the second hard mask layer 535 can include TEOS; the gate-width control layer 540 can include an etch control material; the third hard mask layer 545 can include silicon-containing anti-reflective coating (SiARC) material; and the soft mask features 550 can include photoresist material.

Second gate stack 502 is shown that includes a substrate layer 510, a metal gate layer 515, a first hard mask layer 520, a first silicon-containing layer 525, a second silicon-containing layer 530, a second hard mask layer 535, a gate-width control layer 540, a third hard mask layer 545, and a pattern of hardened soft mask features 550a. For example, the substrate layer 510 can include a semiconductor material; the metal gate layer 515 can include HfO₂; the first hard mask layer 520 can include TiN; the first silicon-containing layer 525 can include amorphous silicon (a-Si); the second silicon-containing layer 530 can include SiN; the second hard mask layer 535 can include TEOS; the gate-width control layer 540 can include an etch control material; the third hard mask layer 545 can include SiARC material; and the hardened soft mask features 550a can include ArF photoresist material 551 and hardened ArF photoresist material 552.

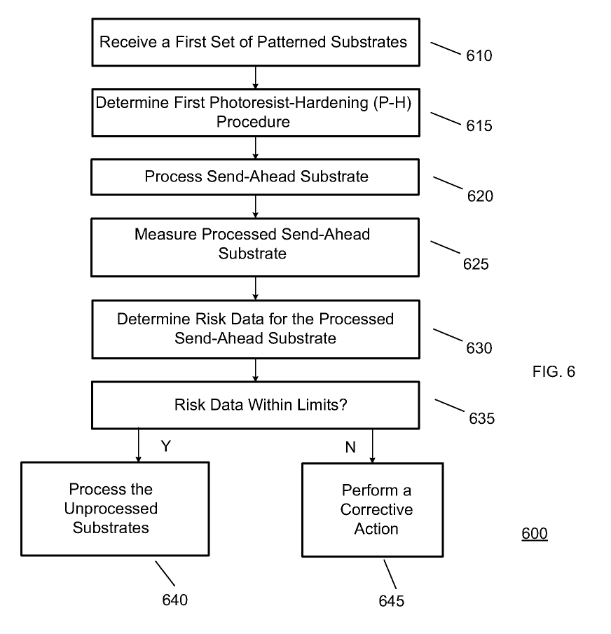

FIG. 6 illustrates a simplified flow diagram of a procedure 600 for processing substrates using a Photoresist-Hardening (P-H) in accordance with embodiments of the invention.

In 610, a first set of patterned substrates can be received by a transfer subsystem (170, FIG. 1) that can be coupled to a Photoresist-Hardening (P-H) subsystem (150, FIG. 1). Each patterned substrate can have a first patterned soft-mask layer and a plurality of additional layers, and the first patterned soft-mask layer can include a plurality of gate-related soft-mask features and at least one periodic evaluation structure. One or more of the controllers (114, 124, 134, 144, 154, 164, and 190) can be used to receive, determine, and/or send real-time and/or historical data associated with one or more of the first set of patterned substrates. For example, the real-time and/or historical data can include material data for the first patterned soft-mask layer, metrology data for the gate-related soft-mask features, and metrology data for the at least one periodic evaluation structure. For example, the metrology data can include profile data, diffraction signal data, CD data, and SWA data.

In 615, a first Photoresist-Hardening (P-H) procedure can be determined for the Photoresist-Hardening (P-H) subsystem (150, FIG. 1), and the P-H subsystem can be as shown in (FIGS. 2, 3, and 4). The first P-H procedure can be configured to create a plurality of hardened soft-mask (photoresist) features and at least one hardened periodic structure in a hardened soft-mask layer by exposing the first patterned soft-mask layer to plasma and a DC voltage.

In 620, a send-ahead substrate can be processed in the selected P-H subsystem using the first P-H procedure, and the processed send-ahead substrate includes the plurality of hardened soft-mask (photoresist) features and the at least one hardened periodic structure.

In 625, the send-ahead substrate can be transferred to the evaluation subsystem (160, FIG. 1), and measurement data can be obtained for the processed send-ahead substrate using diffraction signal data from the at least one hardened periodic structure.

In 630, first risk data for the processed send-ahead substrate can be determined by comparing the measurement data to first P-H-related limits. In some examples, risk data can be determined for the first set of patterned substrates using the first risk data for the processed send-ahead substrate. In addition, confidence data can be determined for the processed send-ahead substrate and/or the first set of patterned substrates.

In 635, a query can be performed to determine if the risk data is less than a first P-H risk limit. When the risk data is less than a first P-H risk limit, procedure 600 can branch to 640. When the risk data is not less than a first P-H risk limit, procedure 600 can branch to 645.

In 640, the unprocessed substrates remaining in the first set of patterned substrates can be processed.

In 645, a corrective action can be performed.

In some examples, corrective actions can include stopping the processing, pausing the processing, re-evaluating one or more of the substrates, re-measuring one or more of the substrates, re-inspecting one or more of the substrates, re-working one or more of the substrates, storing one or more of the substrates, cleaning one or more of the substrates, delaying one or more of the substrates, or stripping one or more of the substrates, or any combination thereof.

Corrective actions can include calculating new and/or updated P-H-related maps for the substrates. In addition, corrective actions can include increasing the number of required evaluation sites by one or more when one or more values in the P-H-related map are not within a limit, and decreasing the number of required evaluation sites by one or more when one or more values in the P-H-related map are within the limit.

In some examples, individual and/or total confidence values for the P-H procedure can be compared to individual and/or total confidence limits. The processing of a set of substrates can continue, if one or more of the confidence limits are met, or corrective actions can be applied if one or more of the confidence limits are not met. Corrective actions can include establishing confidence values for one or more additional substrates in the set of substrates, comparing the confidence values for one or more of the additional substrates to additional confidence limits, and either continuing the P-H procedure, if one or more of the additional confidence limits are met, or stopping the P-H procedure, if one or more of the additional confidence limits are not met.

In other examples, individual and/or total risk values for the substrate can be compared to individual and/or total risk limits. The processing of a set of substrates can continue, if one or more of the risk limits are met, or corrective actions can be applied if one or more of the risk limits are not met. Corrective actions can include establishing risk values for one or more additional substrates in the set of substrates, comparing the risk values for one or more of the additional substrates to additional risk limits, and either continuing P-H procedure, if one or more of the additional risk limits are met, or stopping the P-H procedure, if one or more of the additional risk limits are not met.

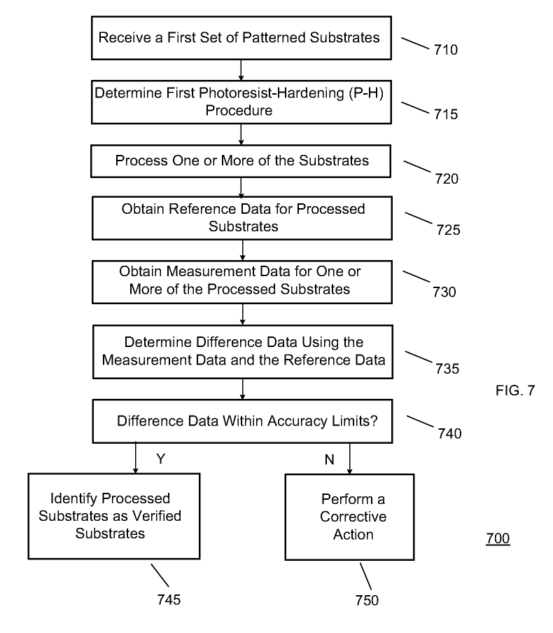

FIG. 7 illustrates a simplified flow diagram of a procedure 700 for processing substrates using a Photoresist-Hardening (P-H) procedure in accordance with embodiments of the invention.

In 710, a first set of patterned substrates can be received by a transfer subsystem (170, FIG. 1) that can be coupled to a Photoresist-Hardening (P-H) subsystem (150, FIG. 1). Each patterned substrate can have a first patterned soft-mask layer and a plurality of additional layers, and the first patterned soft-mask layer can include a plurality of gate-related soft-mask features and at least one periodic evaluation structure. One or more of the controllers (114, 124, 134, 144, 154, 164, and 190) can be used to receive, determine, and/or send real-time and/or historical data associated with one or more of the first set of patterned substrates. For example, the real-time and/or historical data can include material data for the first patterned soft-mask layer, metrology data for the gate-related soft-mask features, and metrology data for the at least one periodic evaluation structure. For example, the metrology data can include profile data, diffraction signal data, CD data, and SWA data. In addition, the first P-H procedure can be based on material properties for the gate-related soft-mask feature.

In 715, a first Photoresist-Hardening (P-H) procedure can be determined for the Photoresist-Hardening (P-H) subsystem (150, FIG. 1), and the P-H subsystem can be as shown in (FIGS. 2, 3, 4A, 4B, and 4C). The first P-H procedure can be configured to create a plurality of hardened soft-mask (photoresist) features and at least one hardened periodic structure in a hardened soft-mask layer by exposing the first patterned soft-mask layer to plasma and a DC voltage.

In 720, one or more of the first set of patterned substrates can be processed using one or more available P-H subsystems using the first P-H procedure, and the processed substrates can include the plurality of hardened soft-mask (photoresist) features and the at least one hardened periodic structure.

In 725, reference and/or verification data can be obtained for the processed substrates.

In 730, one or more of the processed substrates can be transferred to the evaluation subsystem (160, FIG. 1), and measurement data can be obtained for the measured substrate using diffraction signal data from the at least one hardened periodic structure.

In 735, difference data can be determined using the reference data and/or the verification data and the measurement data.

In 740, a query can be performed to determine if the difference data is less than a first accuracy limit. When the difference data is less than a first accuracy limit, procedure 700 can branch to 745. When the risk data is not less than a first P-H risk limit, procedure 700 can branch to 750.

In 745, the processed substrates can be identified as verified substrates. In addition, the first P-H procedure can be identified as a verified procedure when the difference data is less than a first verification limit.

In 750, a corrective action can be performed.

In some examples, corrective actions can include stopping the processing, pausing the processing, re-evaluating one or more of the substrates, re-measuring one or more of the substrates, re-inspecting one or more of the substrates, re-working one or more of the substrates, storing one or more of the substrates, cleaning one or more of the substrates, delaying one or more of the substrates, or stripping one or more of the substrates, or any combination thereof.

Corrective actions can include calculating new and/or updated verification data for the P-H procedures. In addition, corrective actions can include increasing the number of required measurements when one or more P-H-related data items are not within a limit, and decreasing the number of required measurements when one or more P-H-related data items are within the limit.

In some examples, individual and/or total confidence values for the P-H procedure can be compared to individual and/or total confidence limits. The processing of a set of substrates can continue, if one or more of the confidence limits are met, or corrective actions can be applied if one or more of the confidence limits are not met. Corrective actions can include establishing confidence values for one or more additional substrates in the set of substrates, comparing the confidence values for one or more of the additional substrates to additional confidence limits, and either continuing the P-H procedure, if one or more of the additional confidence limits are met, or stopping the P-H procedure, if one or more of the additional confidence limits are not met.

In other examples, individual and/or total risk values for the substrate can be compared to individual and/or total risk limits. The processing of a set of substrates can continue, if one or more of the risk limits are met, or corrective actions can be applied if one or more of the risk limits are not met. Corrective actions can include establishing risk values for one or more additional substrates in the set of substrates, comparing the risk values for one or more of the additional substrates to additional risk limits, and either continuing P-H procedure, if one or more of the additional risk limits are met, or stopping the P-H procedure, if one or more of the additional risk limits are not met.

The substrates can include one or more layers that can include semiconductor material, carbon material, dielectric material, glass material, ceramic material, metallic material, oxidized material, mask material, or planarization material, or a combination thereof.

In other embodiments, one or more substrates can be processed using a verified Photoresist-Hardening (P-H) procedure. When a verified P-H procedure is used, one or more verified structures can be created on a substrate (“golden wafer”). When the substrate is examined, a test reference structure can be selected from a number of verified structures on the substrate. During the examination, examination data can be obtained from the test reference structure. A best estimate structure and associated best estimate data can be selected from the P-H procedure library that includes verified structures and associated data. One or more differences can be calculated between the test reference structure and the best estimate structure from the library, the differences can be compared to matching criteria, creation criteria, or product requirements, or any combination thereof. When matching criteria are used, the test reference structure can be identified as a member of the P-H procedure library, and the current substrate can be identified as a reference “golden” substrate if the matching criteria are met or exceeded. When creation criteria are used, the test reference structure can be identified as a new member of the P-H procedure library, and the current substrate can be identified as a verified reference substrate if the creation criteria are met. When product requirement data is used, the test reference structure can be identified as a verified structure, and the substrate can be identified as verified production substrate if one or more product requirements are met. Corrective actions can be applied if one or more of the criteria or product requirements are not met. P-H procedure confidence data and/or risk data can be established for the test reference structure using the test reference structure data and the best estimate structure data.

When P-H-related structures are produced and/or examined, accuracy and/or tolerance limits can be used. When these limits are not correct, refinement procedures can be performed. Alternatively, other procedures can be performed, other sites can be used, or other substrates can be used. When a refinement procedure is used, the refinement procedure can utilize bilinear refinement, Lagrange refinement, Cubic Spline refinement, Aitken refinement, weighted average refinement, multi-quadratic refinement, bi-cubic refinement, Turran refinement, wavelet refinement, Bessel's refinement, Everett refinement, finite-difference refinement, Gauss refinement, Hermite refinement, Newton's divided difference refinement, osculating refinement, or Thiele's refinement algorithm, or a combination thereof.

In some embodiments, the P-H procedure library data can include goodness of fit (GOF) data, creation rules data, measurement data, inspection data, verification data, map data, confidence data, accuracy data, process data, or uniformity data, or any combination thereof.

In some embodiments, the historical and/or real-time data can include P-H-related maps, substrate-related maps, process-related maps, damage-assessment maps, reference maps, measurement maps, prediction maps, risk maps, inspection maps, verification maps, evaluation maps, particle maps, and/or confidence map(s) for one or more substrates. In addition, some P-H procedures may use substrate maps that can include one or more Goodness Of Fit (GOF) maps, one or more thickness maps, one or more gate-related maps, one or more Critical Dimension (CD) maps, one or more CD profile maps, one or more material related maps, one or more structure-related maps, one or more sidewall angle maps, one or more differential width maps, or a combination thereof.

When substrate maps are created and/or modified, values may not be calculated and/or required for the entire substrate, and a substrate map may include data for one or more sites, one or more chip/dies, one or more different areas, and/or one or more differently shaped areas. For example, a processing chamber may have unique characteristics that may affect the quality of the processing results in certain areas of the substrate. In addition, a manufacturer may allow less accurate process and/or evaluation data for chips/dies in one or more regions of the substrate to maximize yield. When a value in a map is close to a limit, the confidence value may be lower than when the value in a map is not close to a limit. In addition, the accuracy values can be weighted for different chips/dies and/or different areas of the substrate. For example, a higher confidence weight can be assigned to the accuracy calculations and/or accuracy data associated with one or more of the previously used evaluation sites.

In addition, process result, measurement, inspection, verification, evaluation, and/or prediction maps associated with one or more processes may be used to calculate a confidence map for a substrate. For example, values from another map may be used as weighting factors.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

Thus, the description is not intended to limit the invention and the configuration, operation, and behavior of the present invention has been described with the understanding that modifications and variations of the embodiments are possible, given the level of detail present herein. Accordingly, the preceding detailed description is not mean or intended to, in any way, limit the invention—rather the scope of the invention is defined by the appended claims.

What is claimed:

1. A photoresist-hardening (P-H) subsystem, comprising:
a photoresist-hardening (P-H) chamber coupled to a transfer subsystem, wherein the P-H chamber is configured to perform a first photoresist-hardening (P-H) procedure;
a multi-output supply system coupled to an upper DC electrode configured in a first upper assembly in the P-H chamber, wherein the multi-output supply system provides a direct current (DC) voltage to the upper DC electrode;
a remote plasma system coupled to a remote plasma injection plenum configured in a second upper assembly in the P-H chamber, wherein the remote plasma injection plenum comprises a plurality of flow channels configured to provide one or more remote plasma species to a processing region in the P-H chamber;
a substrate holder coupled within the P-H chamber using a DC isolation means, wherein the substrate holder is configured to hold a patterned substrate having a patterned photoresist layer thereon;
a pressure control system configured to control pressure within the P-H chamber wherein the pressure within the P-H chamber varies between approximately 5 mTorr and approximately 400 mTorr during the first P-H procedure;
a lower electrode configured in the substrate holder;
a low frequency generator configured to apply low frequency signal power to the lower electrode to establish and maintain a first photoresist-hardening (P-H) plasma using the one or more remote plasma species; and
a controller coupled to the multi-output supply system, the remote plasma system, the pressure control system, and the low frequency generator, the controller being configured to determine material data for the patterned photoresist layer and establish the first photoresist-hardening (P-H) procedure using the determined material data.

2. The P-H subsystem of claim 1, wherein the P-H subsystem further comprises:
a gas injection system coupled to an inner gas injection plenum and an outer gas injection plenum configured in a third upper assembly in the P-H chamber, wherein the inner gas injection plenum having a plurality of inner orifices therein, and the outer gas injection plenum having a plurality of outer orifices therein.

3. The P-H subsystem of claim 2, wherein the inner gas injection plenum and the inner orifices are configured to provide a first process gas to an inner region of the P-H chamber during the first P-H procedure, wherein the first process gas includes at least one fluorocarbon gas and at least one inert gas, a first fluorocarbon gas flow rate varying between approximately 10 sccm and approximately 50 sccm and a first inert gas flow rate varying between approximately 3 sccm and approximately 20 sccm, wherein the fluorocarbon gas comprises C₄F₆, C₄F₈, C₅F₈, CHF₃, or CF₄, or any combination thereof, and the inert gas comprises Argon (Ar), Helium (He), Krypton (Kr), Neon (Ne), Radon (Rn), or Xenon (Xe), or any combination thereof, and wherein the outer gas injection plenum and the outer orifices are configured to provide a second process gas to an outer region of the P-H chamber during the first P-H procedure, wherein the second process gas includes at least one second fluorocarbon gas and at least one second inert gas, a second fluorocarbon gas flow rate varying between approximately 2 sccm and approximately 50 sccm and a second inert gas flow rate varying between approximately 2 sccm and approximately 100 sccm, wherein the second fluorocarbon gas comprises C₄F₆, C₄F₈, C₅F₈, CHF₃, or CF₄, or any combination thereof, and the second inert gas comprises Argon (Ar), Helium (He), Krypton (Kr), Neon (Ne), Radon (Rn), or Xenon (Xe), or any combination thereof.

4. The P-H subsystem of claim 3, wherein the first process gas includes CO and a first CO flow rate varies between approximately 2 sccm and approximately 10 sccm, and wherein the second process gas includes CO and a second CO flow rate varies between approximately 2 sccm and approximately 20 sccm.

5. The P-H subsystem of claim 1, wherein the substrate holder comprises dual backside gas elements coupled to a backside gas system and temperature control elements coupled to a temperature control system configured to establish a first edge temperature and a first center temperature for the patterned substrate.

6. The P-H subsystem of claim 5, wherein the first edge temperature and the first center temperature are between approximately 0 degrees Celsius and approximately 100 degrees Celsius,

7. The P-H subsystem of claim 1, wherein the low frequency generator is configured to operate in a first frequency range from approximately 10 Hz. to approximately 100 kHz and the low frequency signal power ranges from approximately 10 watts to approximately 700 watts during the first P-H procedure.

8. The P-H subsystem of claim 1, wherein the DC supply voltage ranges from approximately −2000 volts (V) to approximately 1000 V.

9. The P-H subsystem of claim 1, wherein the remote plasma injection plenum and the plurality flow channels are configured to provide a first remote plasma species into the P-H chamber during the first P-H procedure, wherein the first remote plasma species includes Argon (Ar) and a first Ar flow rate varying between approximately 10 sccm and approximately 50 sccm wherein the remote plasma system is configured to provide the first remote plasma species to the remote plasma injection plenum during a first time.

10. The P-H subsystem of claim 9, wherein the remote plasma injection plenum and the plurality flow channels are configured to provide a second remote plasma species into the P-H chamber during the first P-H procedure, wherein the second remote plasma species includes carbon monoxide (CO) and a first CO flow rate varying between approximately 10 sccm and approximately 50 sccm wherein the remote plasma system is configured to provide the second remote plasma species to the remote plasma injection plenum during a second time.

11. The P-H subsystem of claim 1, wherein the upper DC electrode comprises an inner DC electrode and an outer DC electrode configured in the first upper assembly, wherein the multi-output supply system provides a first DC supply voltage to the inner DC electrode and provides a second DC supply voltage to the outer DC electrode.

12. The P-H subsystem of claim 1, wherein the remote plasma injection plenum comprises an inner remote plasma injection plenum and an outer remote plasma injection plenum configured in the second upper assembly in the P-H chamber, wherein the inner remote plasma injection plenum comprises a plurality of inner flow channels configured to provide a first remote plasma species to an inner processing region in the P-H chamber, and the outer remote plasma injection plenum comprises a plurality of outer flow channels configured to provide a second remote plasma species to an outer processing region in the P-H chamber.

13. A method of processing a patterned substrate using a photoresist-hardening (P-H) subsystem, the method comprising:
transferring the patterned substrate into a photoresist-hardening (P-H) chamber using a transfer subsystem coupled to the P-H chamber, the patterned substrate having a patterned photoresist layer thereon;
positioning the patterned substrate on a substrate holder configured within the P-H chamber, wherein the substrate holder is coupled to the P-H chamber using a DC isolation means;
determining material data for the patterned photoresist layer; and
establishing a first photoresist-hardening (P-H) plasma in the P-H chamber using a first photoresist-hardening (P-H) procedure determined using the material data in the patterned photoresist layer.

14. The method of claim 13, further comprising:
providing one or more remote plasma species to a processing region above the patterned substrate in the P-H chamber using a remote plasma system coupled to a remote plasma injection plenum configured in an upper assembly in the P-H chamber, wherein the remote plasma injection plenum comprises a plurality of flow channels configured to provide the one or more remote plasma species to the processing region in the P-H chamber;
providing a DC voltage to an upper DC electrode in the upper assembly during the P-H procedure, wherein a direct current (DC) supply system is coupled to the upper DC electrode and is configured to provide the DC voltage to the upper DC electrode;
establishing a pressure within the P-H chamber, wherein a pressure control system is coupled to the P-H chamber and is configured to control the pressure within the P-H chamber, the pressure within the P-H chamber varying between approximately 5 mTorr and approximately 400 mTorr during the first P-H procedure;
applying a low frequency signal power to a lower electrode configured in the substrate holder, wherein a low frequency generator is coupled to the lower electrode and is configured to apply the low frequency signal power to the lower electrode to establish and/or maintain the first photoresist-hardening (P-H) plasma using the one or more remote plasma species.

15. The method of claim 14, wherein an inner gas injection plenum and inner orifices are configured to provide a first process gas to an inner region of the P-H chamber during the first P-H procedure, wherein the first process gas includes at least one fluorocarbon gas and at least one inert gas, a first fluorocarbon gas flow rate varying between approximately 10 sccm and approximately 50 sccm and a first inert gas flow rate varying between approximately 3 sccm and approximately 20 sccm, wherein the fluorocarbon gas comprises C₄F₆, C₄F₈, C₅F₈, CHF₃, or CF₄, or any combination thereof, and the inert gas comprises Argon (Ar), Helium (He), Krypton (Kr), Neon (Ne), Radon (Rn), or Xenon (Xe), or any combination thereof, and wherein an outer gas injection plenum and outer orifices are configured to provide a second process gas to an outer region of the P-H chamber during the first P-H procedure, wherein the second process gas includes at least one second fluorocarbon gas and at least one second inert gas, a second fluorocarbon gas flow rate varying between approximately 2 sccm and approximately 50 sccm and a second inert gas flow rate varying between approximately 2 sccm and approximately 100 sccm, wherein the second fluorocarbon gas comprises C₄F₆, C₄F₈, C₅F₈, CHF₃, or CF₄, or any combination thereof, and the second inert gas comprises Argon (Ar), Helium (He), Krypton (Kr), Neon (Ne), Radon (Rn), or Xenon (Xe), or any combination thereof.

16. The method of claim 15, wherein the first process gas includes CO and a first CO flow rate varies between approximately 2 sccm and approximately 10 sccm during the first P-H procedure, and wherein the second process gas includes CO and a second CO flow rate varies between approximately 2 sccm and approximately 20 sccm during the first P-H procedure.

17. The method of claim 14, wherein the substrate holder comprises dual backside gas elements coupled to a backside gas system and temperature control elements coupled to a temperature control system configured to establish a first edge temperature and a first center temperature for the patterned substrate, wherein the first edge temperature and the first center temperature are between approximately 0 degrees Celsius and approximately 100 degrees Celsius,

18. The method of claim 14, wherein the low frequency generator is configured to operate in a first frequency range from approximately 10 Hz. to approximately 100 kHz and the low frequency signal power ranges from approximately 10 watts to approximately 700 watts during the first P-H procedure.

19. The method of claim 14, wherein the DC supply voltage ranges from approximately −2000 volts (V) to approximately 1000 V during the first P-H procedure.

20. The method of claim 14, wherein the remote plasma injection plenum and the plurality flow channels are configured to provide a first remote plasma species into the P-H chamber during the first P-H procedure, wherein the first remote plasma species includes Argon (Ar) and a first Ar flow rate varying between approximately 10 sccm and approximately 50 sccm wherein the remote plasma system is configured to provide the first remote plasma species to the remote plasma injection plenum during a first time.

21. The method of claim 20, wherein the remote plasma injection plenum and the plurality flow channels are configured to provide a second remote plasma species into the P-H chamber during the first P-H procedure, wherein the second remote plasma species includes carbon monoxide (CO) and a first CO flow rate varying between approximately 10 sccm and approximately 50 sccm wherein the remote plasma system is configured to provide the second remote plasma species to the remote plasma injection plenum during a second time.
